(19) United States
(12) Patent Application Publication
(10) Pub. No.: US 2018/0083025 A1
(43) Pub. Date: Mar. 22, 2018

(54) SEMICONDUCTOR MEMORY DEVICE AND METHOD OF MANUFACTURING THE SAME

(71) Applicant: Toshiba Memory Corporation, Tokyo (JP)

(72) Inventors: Takuya INATSUKA, Yokkaichi Mie (JP); Tadashi IGUCHI, Yokkaichi Mie (JP)

(21) Appl. No.: 15/688,821

(22) Filed: Aug. 28, 2017

Related U.S. Application Data
(60) Provisional application No. 62/396,517, filed on Sep. 19, 2016.

(51) Int. Cl. H01L 27/11573; H01L 27/1157; H01L 29/66; H01L 21/311; H01L 21/3105; H01L 27/11582; H01L 27/11524; H01L 27/11526; H01L 27/11556

(52) U.S. Cl. CPC H01L 27/11573; H01L 27/1157; H01L 29/66568; H01L 21/31144; H01L 21/31111; H01L 29/495; H01L 27/11582; H01L 27/11524; H01L 27/11526; H01L 27/11556; H01L 21/31053

(57) ABSTRACT

A semiconductor memory device includes a gate insulating film on a semiconductor substrate, a memory cell array in a memory cell region, a first transistor in a peripheral circuit region which surrounds the memory cell region, a second transistor in a scribe region which surrounds the peripheral circuit region, a first stepped structure in the memory cell region, a second stepped structure in the peripheral circuit region facing the first stepped structure, and an interlayer insulating film between the first and second stepped structures. Each of the first and second stepped structures includes a plurality of insulating layers and conductive layers that are alternately stacked on the semiconductor substrate, and an upper surface of an uppermost layer of the first stepped structure, an upper surface of an uppermost layer of the second stepped structure, and an upper surface of the interlayer insulating film are formed on the same plane.

### CROSS-REFERENCE TO RELATED APPLICATIONS

This application is based upon and claims the benefit of priority from U.S. Provisional Patent Application No. 62/396,517, filed on Sep. 19, 2016, the entire contents of which are incorporated herein by reference.

### FIELD

Embodiments described herein relate generally to a semiconductor memory device and a method of manufacturing the same.

### BACKGROUND

A NAND-type flash memory is known as one type of semiconductor memory device.

### BRIEF DESCRIPTION OF THE DRAWINGS

FIG. 1 is a block diagram illustrating a configuration example of a semiconductor memory device according to a first embodiment.

FIG. 2 is a plan view of a semiconductor memory device according to the first embodiment.

FIG. 3 is a perspective view of region E of the semiconductor memory device shown in FIG. 2.

FIG. 4A is a cross-sectional view taken along line 4A-4A of the semiconductor memory device shown in FIG. 2.

FIG. 4B is a cross-sectional view taken along line 4B-4B of the semiconductor memory device shown in FIG. 2.

FIGS. 5A, 6A, 7A, 8A, 9A, 10A, 11A, and 12A are cross-sectional views taken along line 4A-4A of the semiconductor memory device shown in FIG. 2 during different steps of manufacturing the semiconductor memory device.

FIGS. 5B, 6B, 7B, 8B, 9B, 10B, 11B, and 12B are cross-sectional views taken along line 4B-4B of the semiconductor memory device shown in FIG. 2 during different steps of manufacturing the semiconductor memory device.

FIG. 13 is a plan view of a semiconductor memory device according to a second embodiment.

FIG. 14A is a cross-sectional view taken along line 14A-14A of the semiconductor memory device shown in FIG. 13.

FIG. 14B is a cross-sectional view taken along line 14B-14B of the semiconductor memory device shown in FIG. 13.

FIGS. 15A, 16A, 17A, 18A, 19A, 20A, and 21A are cross-sectional views taken along line 14A-14A of the semiconductor memory device shown in FIG. 13 during different steps of manufacturing the semiconductor memory device.

FIGS. 15B, 16B, 17B, 18B, 19B, 20B, and 21B are cross-sectional views taken along line 14B-14B of the semiconductor memory device shown in FIG. 13 during different steps of manufacturing the semiconductor memory device.

### DETAILED DESCRIPTION

According to one embodiment, a semiconductor memory device includes a semiconductor substrate having a main surface, a gate insulating film which covers the main surface of the semiconductor substrate, a memory cell array disposed in a memory cell region, a first transistor disposed in a peripheral circuit region which surrounds the memory cell region, the first transistor having a first gate electrode on the gate insulating film, a second transistor disposed in a scribe region which surrounds the peripheral circuit region, the second transistor having a second gate electrode on the gate insulating film, a first stepped structure disposed in the memory cell region and a second stepped structure disposed in the peripheral circuit region, the first and second stepped structures facing each other and each including a plurality of insulating layers and conductive layers that are alternately stacked on the main surface of the semiconductor substrate, and an interlayer insulating film disposed in a region where the first stepped structure and the second stepped structure face each other. In the semiconductor memory device, an upper surface of an uppermost layer of the first stepped structure, an upper surface of an uppermost layer of the second stepped structure, and an upper surface of the interlayer insulating film are formed on the same plane.

Hereinafter, a semiconductor memory device and a method of manufacturing the same according to the embodiments will be described with reference to the drawings. In each of the drawings, the same components are denoted by the same reference numerals.

### First Embodiment

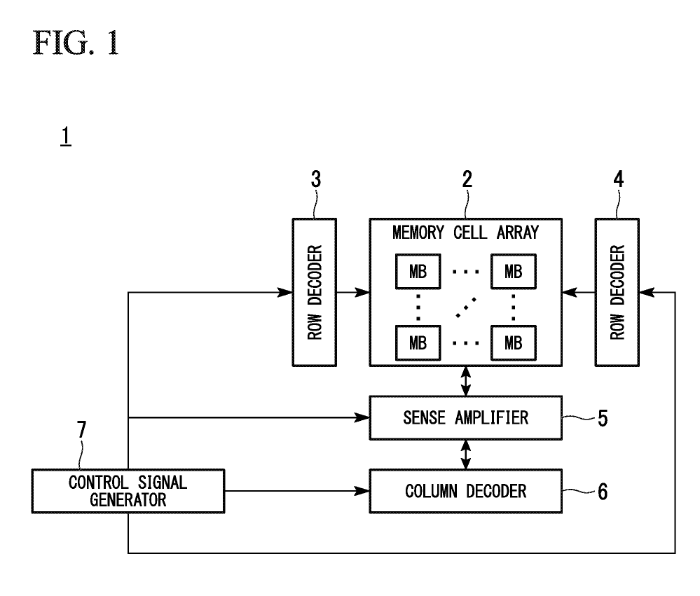

FIG. 1 is a block diagram illustrating a configuration example of a semiconductor memory device of a first embodiment.

A semiconductor memory device 1 according to the first embodiment includes a memory cell array 2, row decoders 3 and 4, a sense amplifier 5, a column decoder 6, and a control signal generator 7.

The memory cell array 2 includes a plurality of memory blocks MB. Each memory block MB includes a plurality of memory transistors (not shown in figure) which constitute a plurality of memory cells arranged in three dimensions. Each memory block MB is a unit for a data erasing operation. The memory blocks MB are separated from each other by a plurality of grooves extending in one direction.

The row decoders 3 and 4 decode a block address signal or the like transmitted from the control signal generator 7. The row decoders 3 and 4 control read and write operations of data of the memory cell array 2.

The sense amplifier 5 detects and amplifies an electrical signal flowing in the memory cell array 2 during the read operation.

The column decoder 6 decodes a column address signal sent from the control signal generator 7 and selectively extracts data by controlling the sense amplifier 5.

The control signal generator 7 generates control signals such as the block address signal and column address signal. The control signal generator 7 controls the row decoders 3 and 4, the sense amplifier 5, and the column decoder 6.

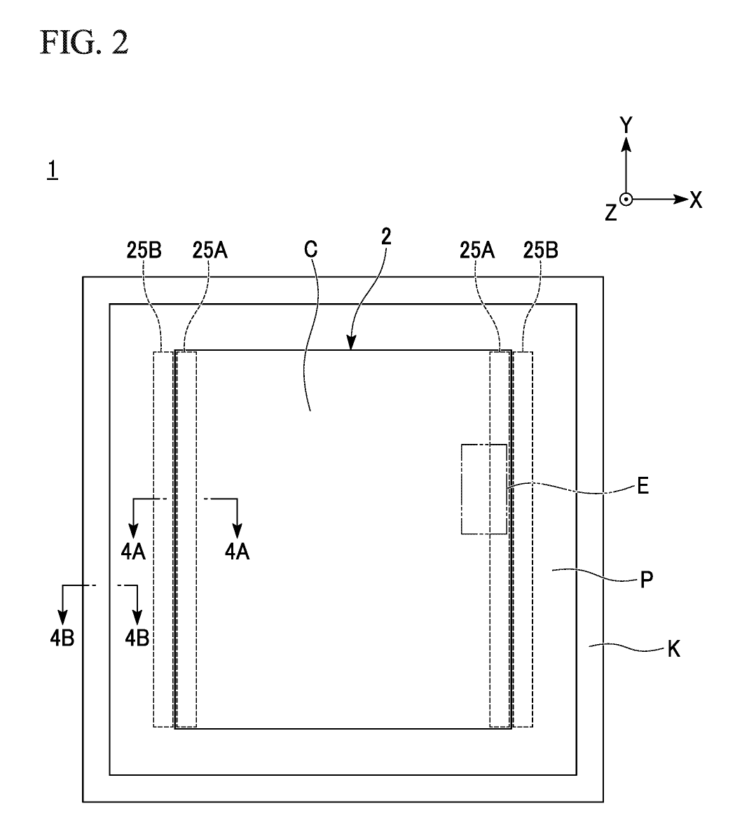

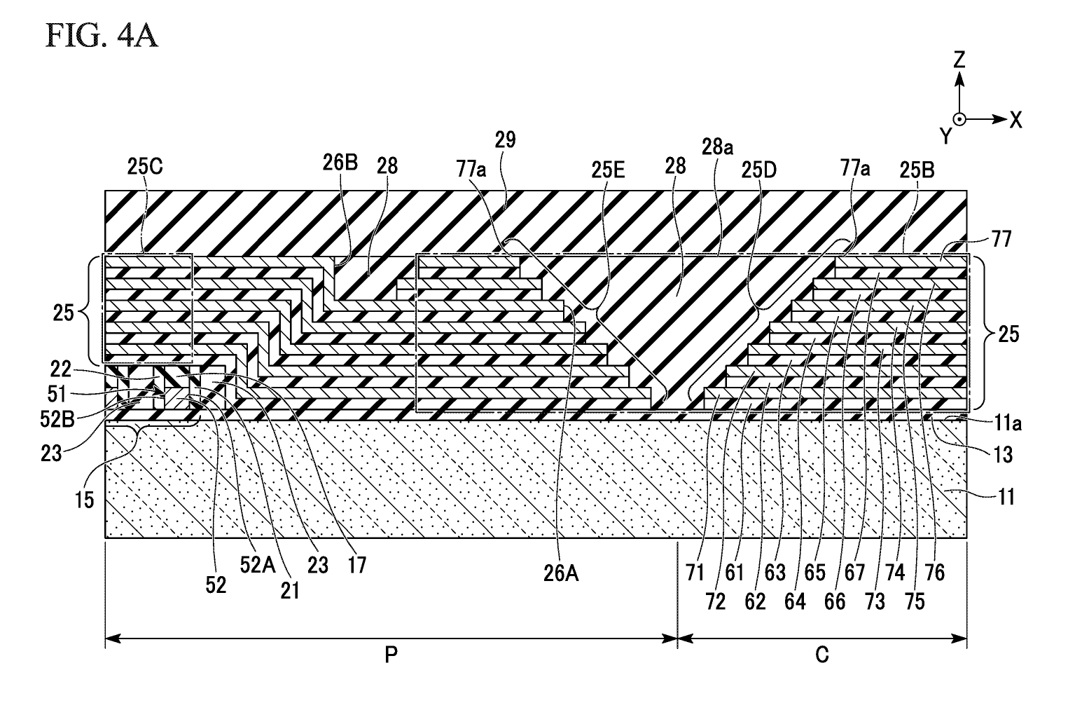

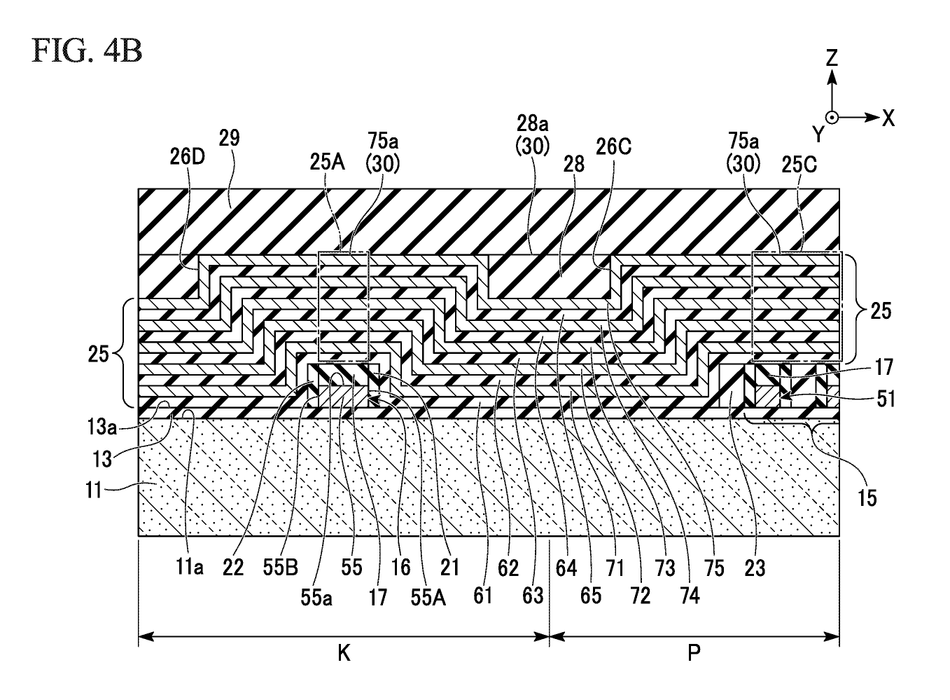

FIG. 2 is a plan view of a semiconductor memory device according to the first embodiment. In FIG. 2, an X direction refers to a direction in which a first stepped part 25D (shown in FIG. 4A) and a second stepped part 25E (shown in FIG. 4A) face each other, a Y direction refers to an extending direction of a portion in which the second stepped part 25E is provided (a direction perpendicular to the X direction) in a peripheral circuit region P, and a Z direction refers to a thickness direction of the semiconductor memory device 1 perpendicular to an X-Y plane. In FIG. 2, the same components as in the semiconductor memory device 1 shown in FIG. 1 are designated by the same reference numerals.

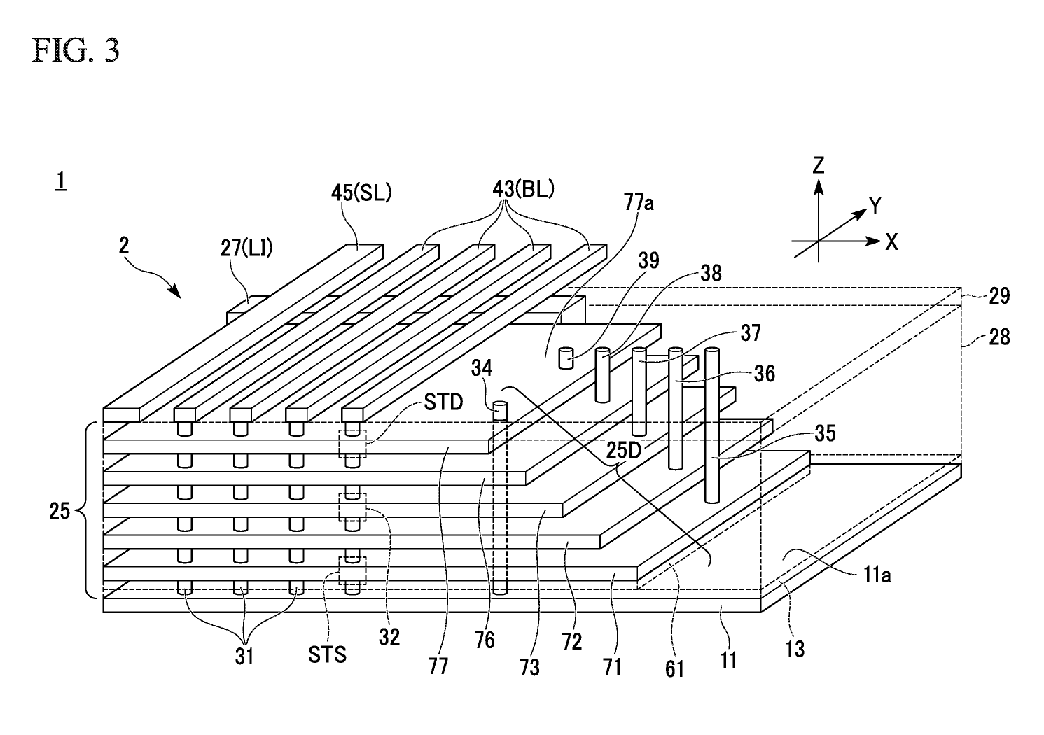

FIG. 3 is a perspective view of a region E of the semiconductor memory device shown in FIG. 2. In FIG. 3, the same components as in the semiconductor memory device 1 shown in FIGS. 1 and 2 are designated by the same reference numerals. FIG. 3 shows an example of the memory cell array 2, and the number, disposition, and the like of each component are not limited to those shown in FIG. 3.

FIG. 4A is a cross-sectional view taken along line 4A-4A of the semiconductor memory device shown in FIG. 2. FIG. 4B is a cross-sectional view taken along line 4B-4B of the semiconductor memory device shown in FIG. 2. In FIGS. 4A and 4B, the same components as in the structures shown in FIGS. 1 to 3 are designated by the same reference numerals.

In FIG. 3, conductive layers 74 and 75 which constitute a layered structure 25 and contact interconnections connected thereto, and insulating layers 62 to 67 are not shown to allow easier viewing of the drawing.

Referring to FIGS. 2, 3, 4A and 4B, the semiconductor memory device 1 according to the first embodiment includes a semiconductor substrate 11, a gate insulating film 13, a first transistor group 15, a plurality of second transistors 16, a cap insulating film 17, lateral walls 21 and 22, an insulating film 23, the layered structure 25, recessed portions 26A to 26D, a conductive portion 27, an interlayer insulating film 28, a thickness adjustment interlayer insulating film 29, memory columnar bodies 31, memory cells 32, a beam columnar body 34, contact interconnections 35 to 39, a plurality of conductive lines 43, and a conductive line 45.

The semiconductor substrate 11 has a main surface 11a. The main surface 11a includes a memory cell region C, the peripheral circuit region P, and a scribe region K. The memory cell region C is a rectangular region and the memory cell array 2 is disposed therein.

The peripheral circuit region P surrounds the memory cell region C and the first transistor group 15 is disposed therein.

The scribe region K surrounds the peripheral circuit region P, and the plurality of second transistors 16 are disposed in the scribe region K. The semiconductor substrate 11 is, for example, a p-type single crystal silicon substrate.

The gate insulating film 13 covers the main surface 11a of the semiconductor substrate 11. The gate insulating film 13 is a gate insulating film of a plurality of first transistors 51 which constitute the first transistor group 15 and the plurality of second transistors 16. As the gate insulating film 13, for example, a silicon oxide film may be used.

The first transistor group 15 includes the plurality of first transistors 51 and is provided in the peripheral circuit region P. The first transistors 51 include the gate insulating film 13, a first gate electrode 52, and a pair of impurity diffusion regions (not shown in figure).

The first gate electrode 52 extends in the Y direction. A plurality of first gate electrodes 52 are arranged in the X direction. The first gate electrode 52 has a pair of side walls 52A and 52B. The side wall 52A is disposed on the side of the memory cell region C. The side wall 52B is disposed on the side of the scribe region K.

The second transistor 16 is provided in the scribe region K. The second transistor 16 includes the gate insulating film 13, a second gate electrode 55, and a pair of impurity diffusion regions (not shown in figure).

The second gate electrode 55 is provided on the gate insulating film 13 positioned in the scribe region K. The second gate electrode 55 extends in the Y direction. The second gate electrode 55 includes side walls 55A and 55B disposed in the X direction. The side wall 55A is disposed on the side of the peripheral circuit region P. The side wall 55B is disposed on the outer side of the scribe region K. A thickness of the second gate electrode 55 is equal to a thickness of the first gate electrode 52.

The cap insulating film 17 covers an upper surface of the first gate electrode 52 and an upper surface of the second gate electrode 55. As the cap insulating film 17, for example, a silicon nitride film may be used.

The lateral wall 21 covers the side wall 52A of the first gate electrode 52 and the side wall 55A of the second gate electrode 55. The lateral wall 22 covers the side wall 52B of the first gate electrode 52 and the side wall 55B of the second gate electrode 55. As the lateral walls 21 and 22, for example, a silicon nitride film may be used.

The insulating film 23 is provided on the side walls 52A and 52B disposed in the peripheral circuit region P. The insulating film 23 fills a groove formed between the side walls 52A and 52B.

An upper surface of the insulating film 23 and an upper surface of the cap insulating film 17 are formed on the same plane. As the insulating film 23, for example, a silicon oxide film may be used.

The layered structure 25 includes insulating layers 61 to 67 and conductive layers 71 to 77 which are alternately layered on the gate insulating film 13, and covers the cap insulating film 17 and the lateral walls 21 and 22.

The first insulating layer 61 covers the main surface 11a of the semiconductor substrate 11, the cap insulating film 17, and the lateral walls 21 and 22. The first insulating layers 61 to 67 are disposed to be layered in a direction away from the semiconductor substrate 11. Thicknesses of the first insulating layers 61 to 67 are equal to each other. The first insulating layers 61 to 67 are, for example, silicon oxide films.

The conductive layer 71 is provided on the first insulating layer 61. The conductive layers 71 to 77 are disposed to be layered in a direction away from the semiconductor substrate 11.

The conductive layer 71 disposed to be the lowermost conductive layer is a source-side selective gate electrode layer (SGS) of a source-side selective transistor (STS). The conductive layer 77 disposed to be the uppermost conductive layer is a drain-side selective gate electrode layer (SGD) of a drain-side selective transistor (STD).

The conductive layers 72 to 76 are gate electrode layers of the memory cells 25. The number of the conductive layers is arbitrary.

Thicknesses of the conductive layers 71 to 77 are equal to each other. The conductive layers 71 to 77 are, for example, tungsten (W).

The layered structure 25 includes a first portion 25A, a second portion 25B, and a third portion 25C. The first portion 25A is disposed above the second gate electrode 55.

The second portion 25B is disposed in a portion of the peripheral circuit region P positioned near the memory cell region C and in the memory cell region C. The second portion 25B includes the insulating layers 61 to 67 and the conductive layers 71 to 77 which are alternately layered.

The second portion 25B includes the first stepped part 25D and a second stepped part 25E which have a stepped structure.

The stepped structure refers to a structure in which, when an end portion in the X direction of an (n)th layer component counted from the main surface 11a side of the semiconductor substrate 11 is at a negative side in the X direction with respect to an end portion in the X direction of an (n+1)th layer component, for example, the correlation is maintained such that an end portion in the X direction of an (n+2)th layer component is at a negative side in the X direction with respect to the end portion in the X-direction of the (n+1)th layer component.

The first stepped part 25D is disposed at an end portion of the memory cell region C. The second stepped part 25E is disposed at an end portion of the peripheral circuit region P positioned on the memory cell region C side. The second stepped part 25E faces the first stepped part 25D in the X direction.

The first stepped part 25D and the second stepped part 25E are provided to be continuous from an upper surface 77a of the conductive layer 77, which is an uppermost surface of the layered structure 25, to the gate insulating film 13.

In the first stepped part 25D and the second stepped part 25E, the conductive layers 71 to 77 are layered such that end portions of the upper conductive layers 72 to 77 are set back in the X direction relative to each end portion of the next lower conductive layers 71 to 76.

Also, the end portions of the conductive layers 71 to 77 refer to certain regions near the end surfaces of the conductive layers.

The third portion 25C is disposed above the first gate electrode 52.

The third portion 25C and the first portion 25A include the insulating layers 61 to 65 and the conductive layers 71 to 75 which are alternately layered and the number of stacked layers thereof is fewer than the number of stacked layers of the third portion 25B.

The uppermost layer of the third portion 25C and the first portion 25A is the conductive layer 75.

A height from the main surface 11a of the semiconductor substrate 11 to the upper surface 77a of the uppermost layer of the second portion 25B is the same as a height from the main surface 11a of the semiconductor substrate 11 to an upper surface 75a of the uppermost layer of the first portion 25A and the third portion 25C.

At the pair of side walls 55A and 55B of the second gate electrode 55, the layered structure 25 is disposed to be continuous from an upper surface 55a above the second gate electrode 55 to an upper surface 13a of the gate insulating film 13.

The recessed portion 26A is formed between the first stepped part 25D and the second stepped part 25E which are disposed near each other. The recessed portion 26A is a V-shaped groove, and the width of the recessed portion 26A in the X-direction is small.

The recessed portion 26B is provided at an upper portion of the layered structure 25 disposed in the peripheral circuit region P. The recessed portion 26B is disposed between the second stepped part 25E and the first transistor group 15.

The recessed portion 26C is provided at an upper portion of the layered structure 25 disposed at a boundary portion between the peripheral circuit region P and the scribe region K. The recessed portion 26C is disposed between the first transistor group 15 and the second transistor 16.

The recessed portion 26D is provided at an upper portion of the layered structure 25 disposed in the scribe region K. Depths of the recessed portions 26B to 26D are smaller than a depth of the recessed portion 26A.

The conductive portion 27 is provided on the main surface 11a of the semiconductor substrate 11. The conductive portion 27 extends in the X direction and the Z direction. In the Y direction, the conductive portion 27 faces side surfaces of the conductive layers 71 to 77. The conductive portion 27 includes, for example, tungsten.

The interlayer insulating film 28 fills the recessed portions 26A to 26D. An upper surface 28a of the interlayer insulating film 28 is a planarized surface.

The upper surface 77a of the uppermost layer of the first stepped part 25D, the upper surface 77a of the uppermost layer of the second stepped part 25E, the upper surface 75a of the first portion 25A, the upper surface 75a of the third portion 25C, and the upper surface 28a of the interlayer insulating film 28 are formed on the same plane 30.

As the interlayer insulating film 28, for example, a silicon oxide film may be used.

The thickness adjustment interlayer insulating film 29 covers the upper surface 28a of the interlayer insulating film 28, the upper surfaces 75a and 77a of the conductive layers 75 and 77 exposed from the interlayer insulating film 28. As the thickness adjustment interlayer insulating film 29, for example, a silicon oxide film may be used.

The plurality of memory columnar bodies 31 are provided in the memory cell region C excluding the first stepped part 25D in the main surface 11a of the semiconductor substrate 11.

The memory columnar bodies 31 penetrate the layered structure 25 in the Z direction. The memory columnar bodies 31 are disposed in an arbitrary layout on the X-Y plane.

An intersecting portion of the memory columnar body 31 and the conductive layer 71 is the source-side selective transistor (STS). An intersecting portion of the memory columnar body 31 and the conductive layer 77 is the drain-side selective transistor (STD). Intersecting portions of the memory columnar bodies 31 and the conductive layers 72 to 76 are memory cells 32.

The drain-side selective transistor (STD), the plurality of memory cells 25, and the source-side selective transistor (STS) formed by the same memory columnar body 31 are connected in series.

The beam columnar body 34 penetrates the first stepped part 25D in the Z direction. The beam columnar body 34 penetrates the conductive layer 77 and reaches the main surface 11a of the semiconductor substrate 11.

The contact interconnections 35 to 39 penetrate the interlayer insulating film 28 provided at the first stepped part 25D and the thickness adjustment interlayer insulating film 29 in the Z direction.

A lower end of the contact interconnection 35 is closest to the main surface 11a of the semiconductor substrate 11. A lower end of the contact interconnection 39 is farthest from the main surface 11a of the semiconductor substrate 11. A lower end of the contact interconnection 36 is closer to the main surface 11a of the semiconductor substrate 11 than lower ends of the contact interconnections 37 and 38. The lower end of the contact interconnection 37 is closer to the main surface 11a of the semiconductor substrate 11 than the lower end of the contact interconnection 38.

Each of the lower ends of the contact interconnections 35 to 39 is connected to any one conductive layer among the conductive layers 71 to 77.

The plurality of conductive lines 43 extend in the Y direction and are arranged in the X direction. The plurality of conductive lines 43 are bit lines (BL).

The conductive line 45 is provided on an upper end of the conductive portion 27. The conductive line 45 extends in the Y direction. The conductive line 45 is a source line (SL).

The plurality of conductive lines 43 and the conductive line 45 includes, for example, tungsten (W).

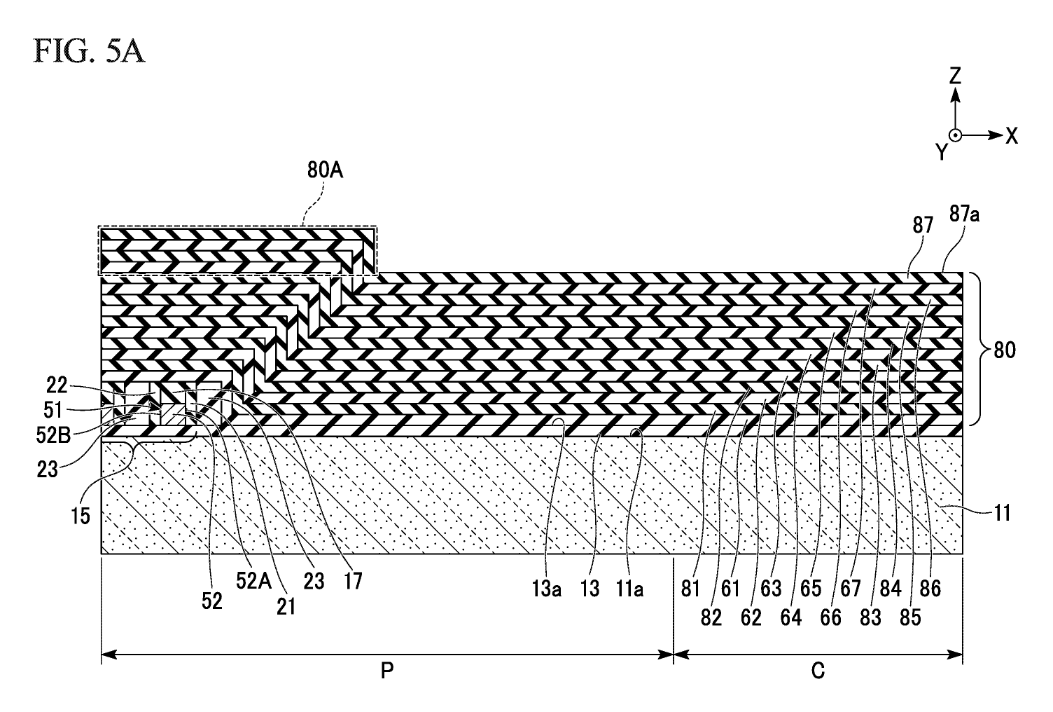

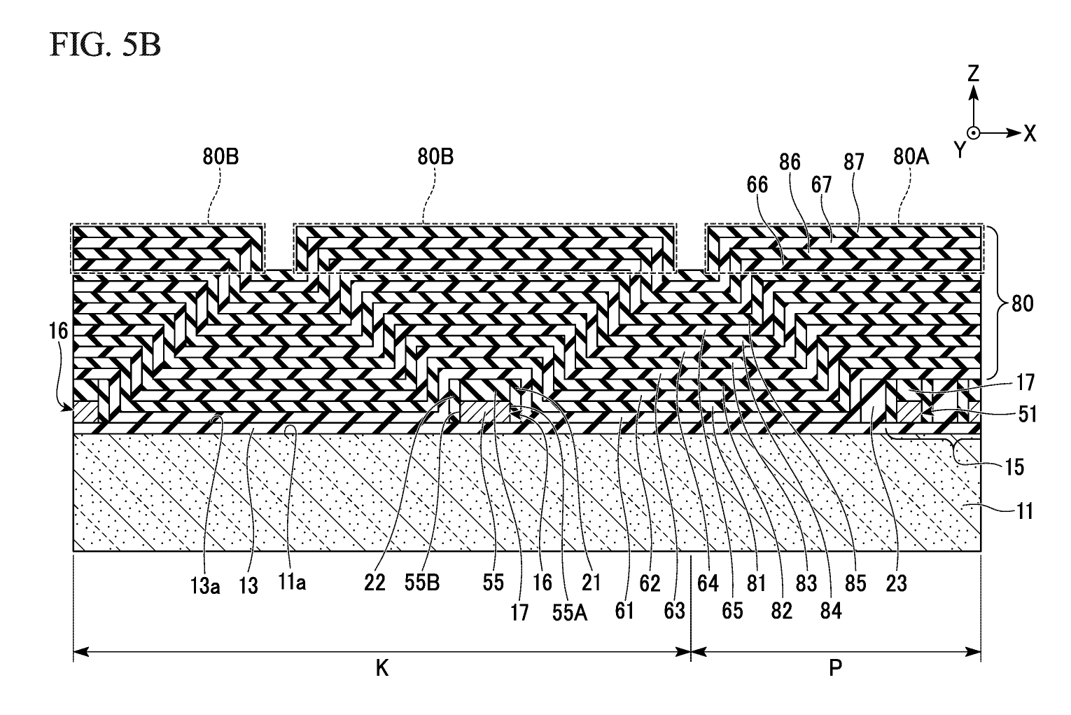

A method of manufacturing the semiconductor memory device 1 according to the first embodiment will be described with reference to FIGS. 5A to 11A and FIGS. 5B to 11B.

FIGS. 5A to 11A and FIGS. 5B to 11B are cross-sectional views showing a process of manufacturing a semiconductor memory device according to the first embodiment.

To obtain the structure shown in FIGS. 5A and 5B, the gate insulating film 13 is formed on the main surface 11a of the semiconductor substrate 11 and then the first transistor group 15, the plurality of second transistors 16, the cap insulating film 17, the lateral walls 21 and 22, and the insulating film 23 are formed.

The first transistor group 15 including the plurality of first transistors 51 and the plurality of second transistors 16 are collectively formed (a first process).

The insulating layers 61 to 67 and sacrificial insulating layers 81 to 87 are alternately layered on the main surface 11a of the semiconductor substrate 11, the cap insulating film 17, and the lateral walls 21 and 22 to form a layered insulation body 80 (a second process).

In this stage, a protrusion 80A disposed above the first transistor group 15 and a protrusion 80B disposed above the second transistors 16 are formed.

The protrusions 80A and 80B protrude upward from an upper surface 87a of the uppermost layer of the layered insulation body 80 formed in the memory cell region C.

The sacrificial insulating layers 81 to 87 are a different type of film from the insulating layers 61 to 67 and can have an etch selectivity with respect to the insulating layers 61 to 67.

As the insulating layers 61 to 67, for example, a silicon oxide film may be used. As the sacrificial insulating layers 81 to 87, for example, a silicon nitride film may be used.

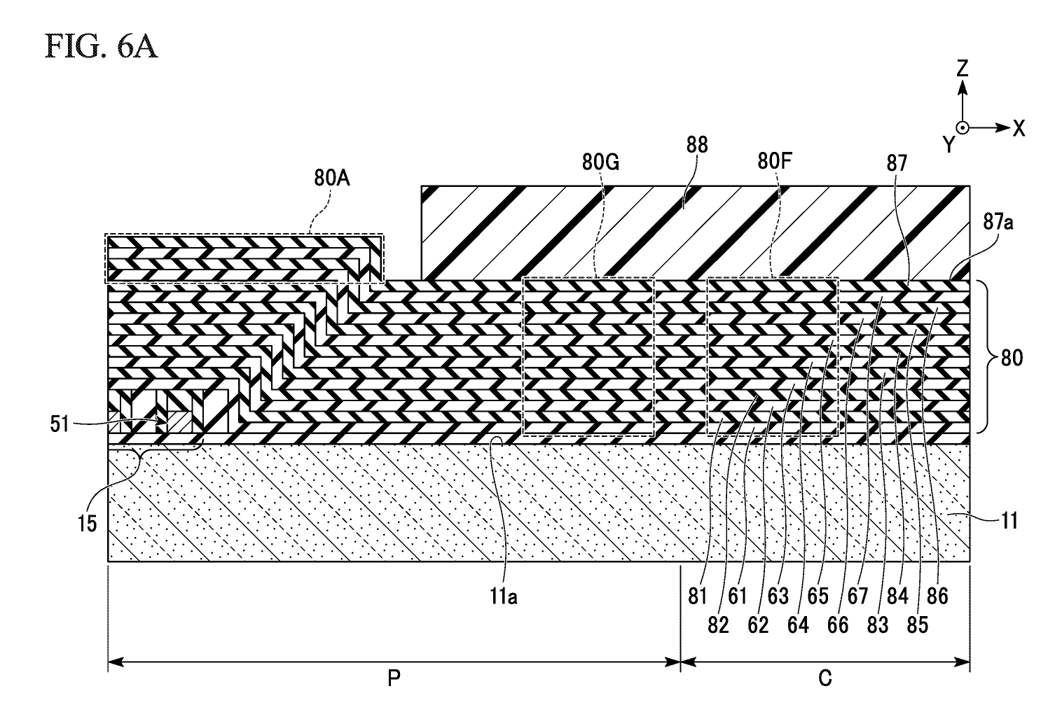

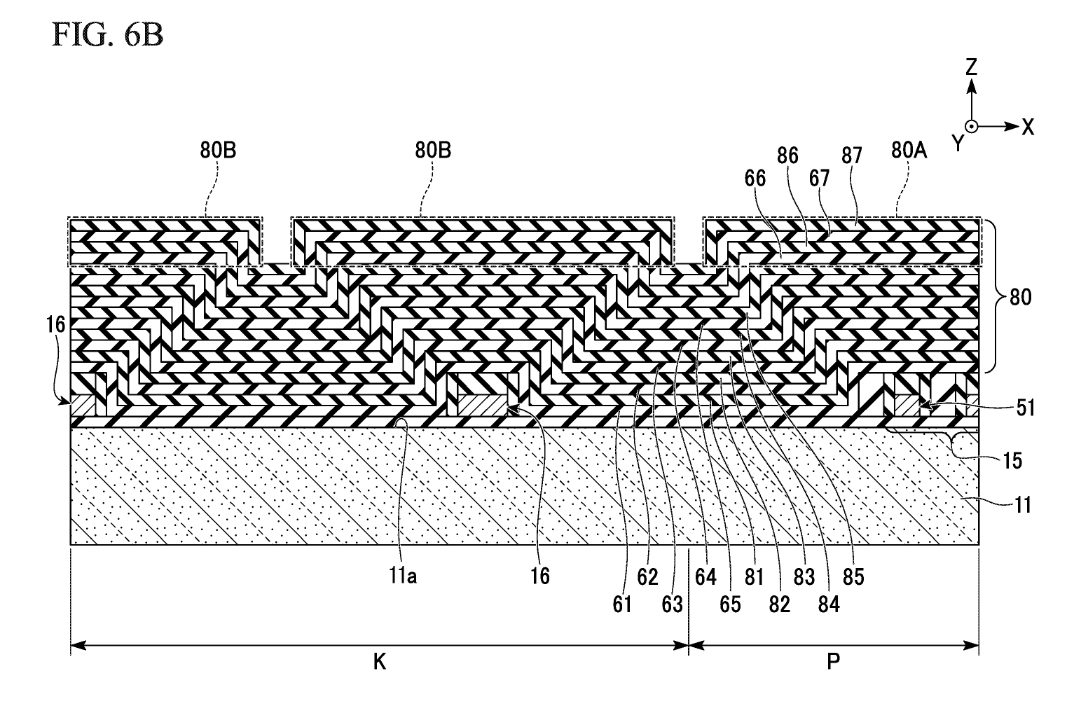

To obtain the structure shown in FIGS. 6A and 6B, an etching mask 88 is formed on the upper surface 87a (the uppermost surface) of the layered insulation body 80 formed in the memory cell region C and a portion of the peripheral circuit region P, in a state in which the protrusions 80A and 80B are exposed.

The etching mask 88 covers an upper surface of a first step formation region 80F formed of the layered insulation body 80 disposed at the end portion of the memory cell region C and an upper surface of a second step formation region 80G formed of the layered insulation body 80 disposed at the end portion of the peripheral circuit region P positioned on the memory cell region C side.

The second step formation region 80G faces the first step formation region 80F in the X direction.

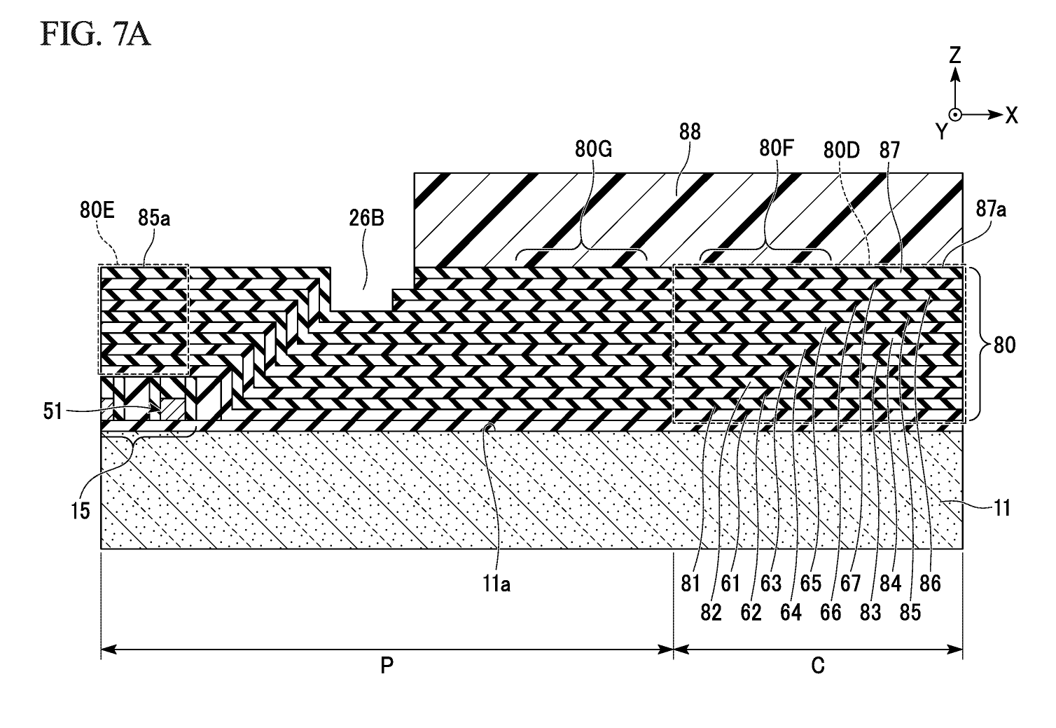

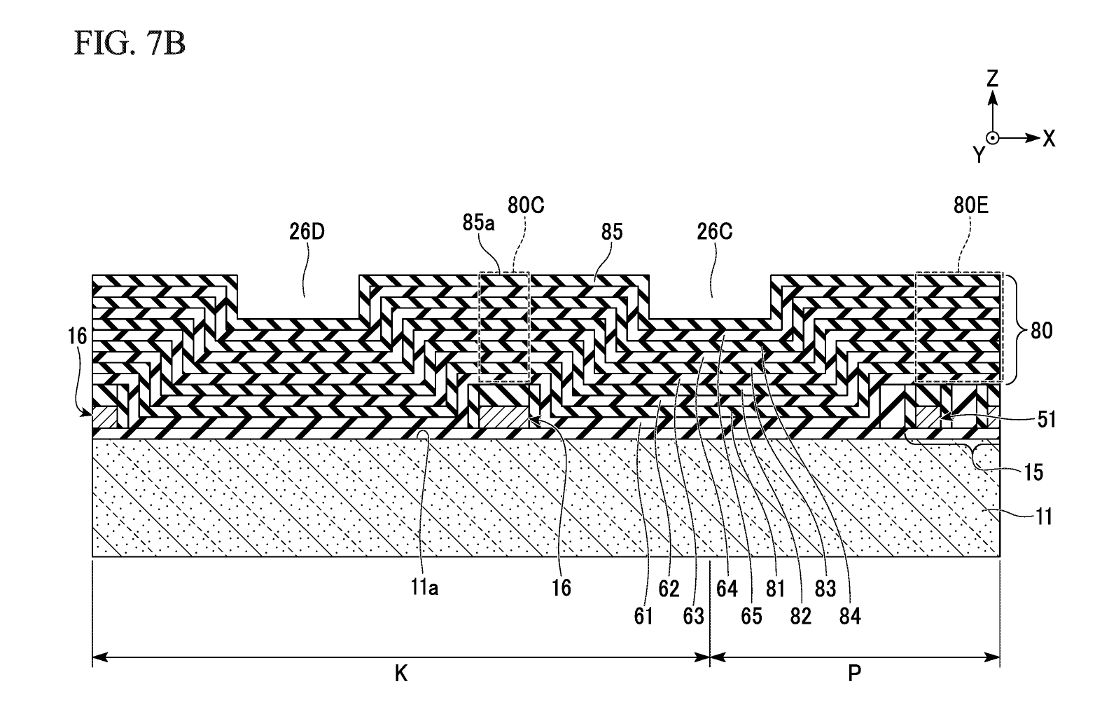

To obtain the structure shown in FIGS. 7A and 7B, the protrusions 80A and 80B which are upper portions of the layered insulation body 80 in the peripheral circuit region P and the scribe region K are removed by anisotropic etching to form the recessed portions 26B to 26D, and then a first layered portion 80C disposed above the second transistors 16 and formed of the layered insulation body 80, and a third layered portion 80E disposed above the first transistor group 15 and formed of the layered insulation body 80.

In this case, a height from the main surface 11a of the semiconductor substrate 11 to an upper surface 85a of the first layered portion 80C, a height from the main surface 11a of the semiconductor substrate 11 to the upper surface 87a of a second layered portion 80D disposed in the memory cell region C and formed of the layered insulation body 80, and a height from the main surface 11a of the semiconductor substrate 11 to the upper surface 85a of the third layered portion 80E are made to be the same (a third process).

After the third process, the etching mask 88 is removed.

In the third process, the insulating layers 66 and 67 and the sacrificial insulating layers 86 and 87 are alternately etched layer by layer, by alternately performing selectively etching the sacrificial insulating layers 86 and 87 and selectively etching the insulating layers 66 and 67.

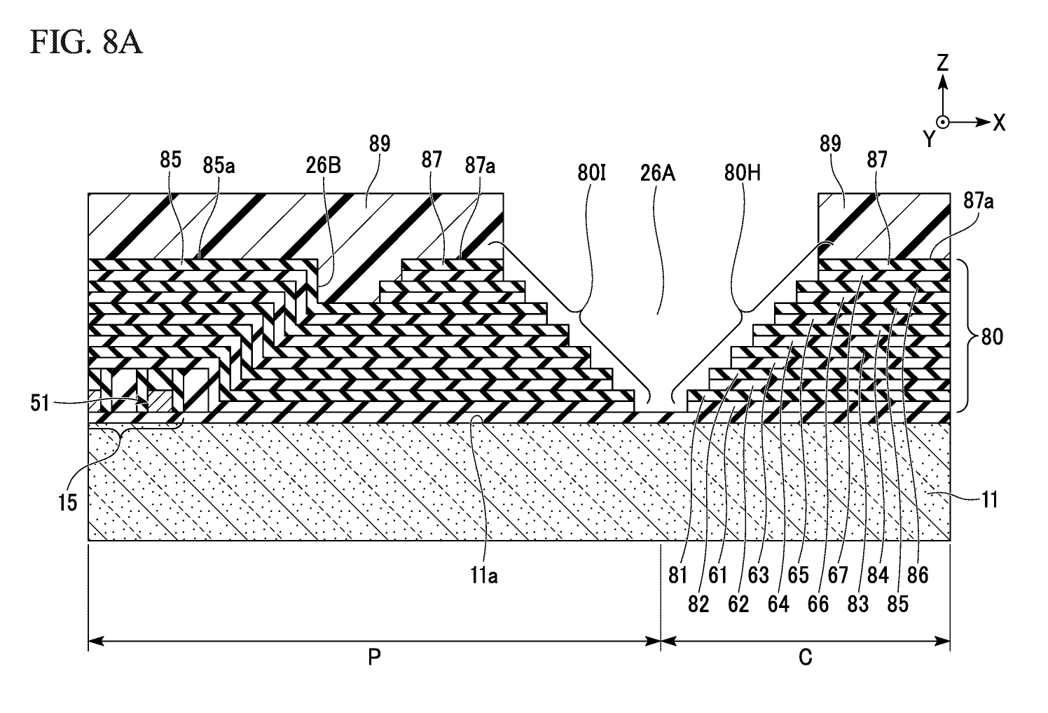

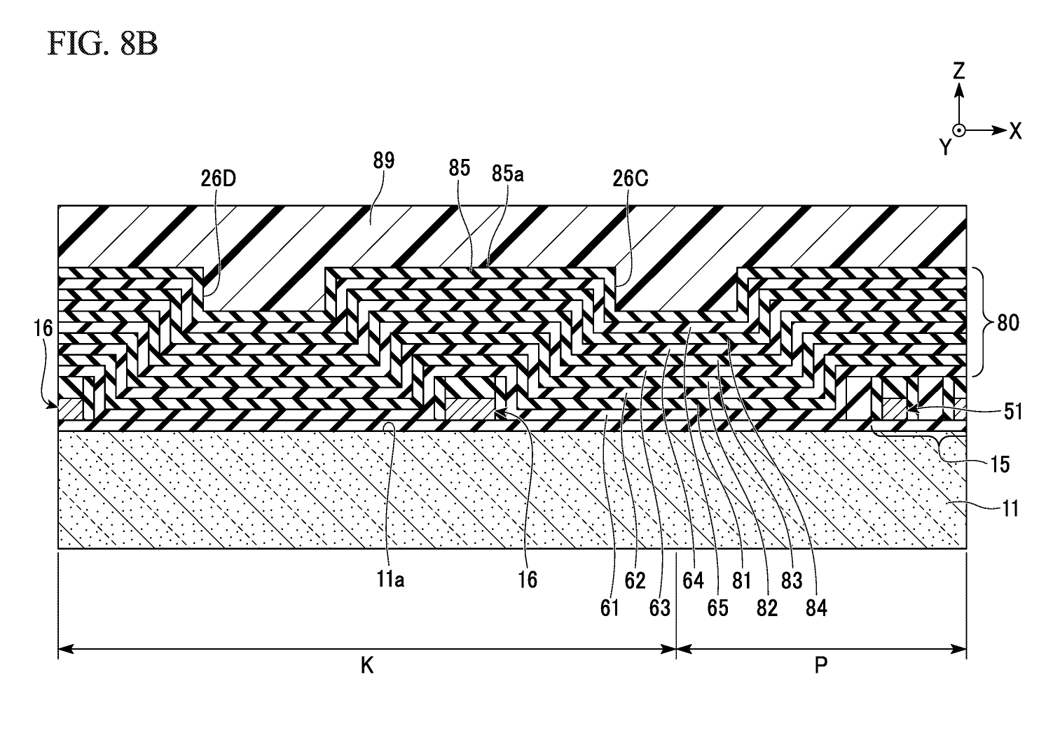

To obtain the structure shown in FIGS. 8A and 8B, an etching mask 89 that exposes a formation region of the recessed portion 26A is formed on the layered insulation body 80.

After the etching mask 89 is formed, the layered insulation body 80 corresponding to the formation regions of a first stepped part 80H, a second stepped part 80I, and the recessed portion 26A is etched to collectively form the first stepped part 80H, the second stepped part 80I, and the recessed portion 26A (a fourth process).

In the above-described fourth process, the second stepped part 80I is formed between the first transistor group 15 and the first stepped part 80H in a state in which the first transistor group 15 is covered by the layered insulation body 80.

The etching mask 89 is removed after the first stepped part 80H, the second stepped part 80I, and the recessed portion 26A are formed.

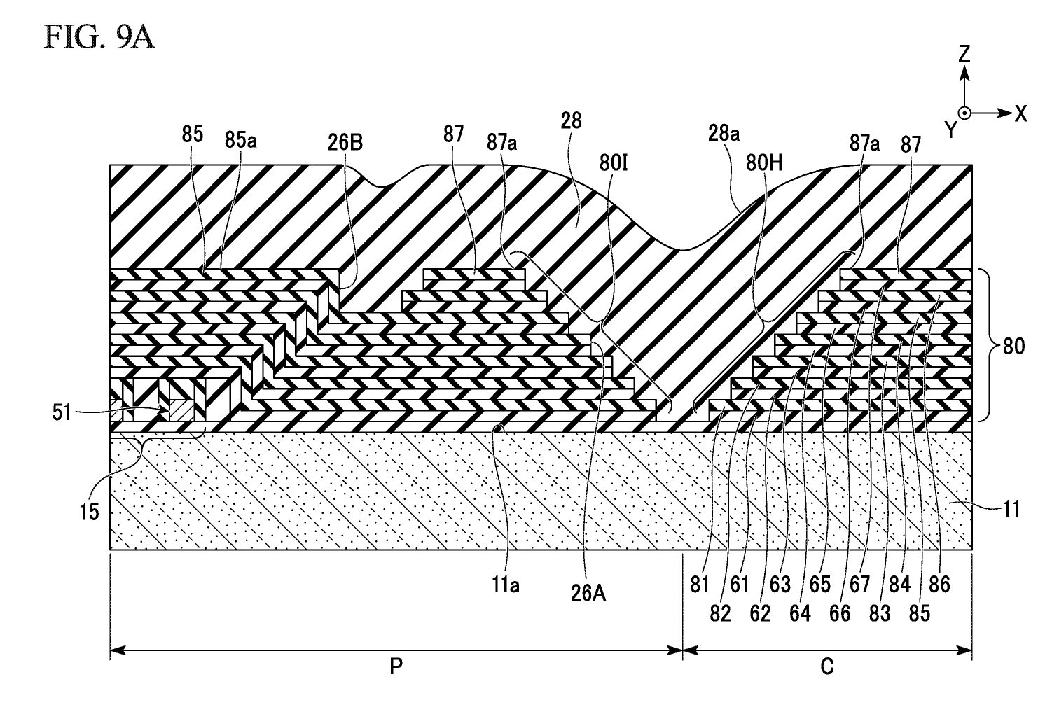

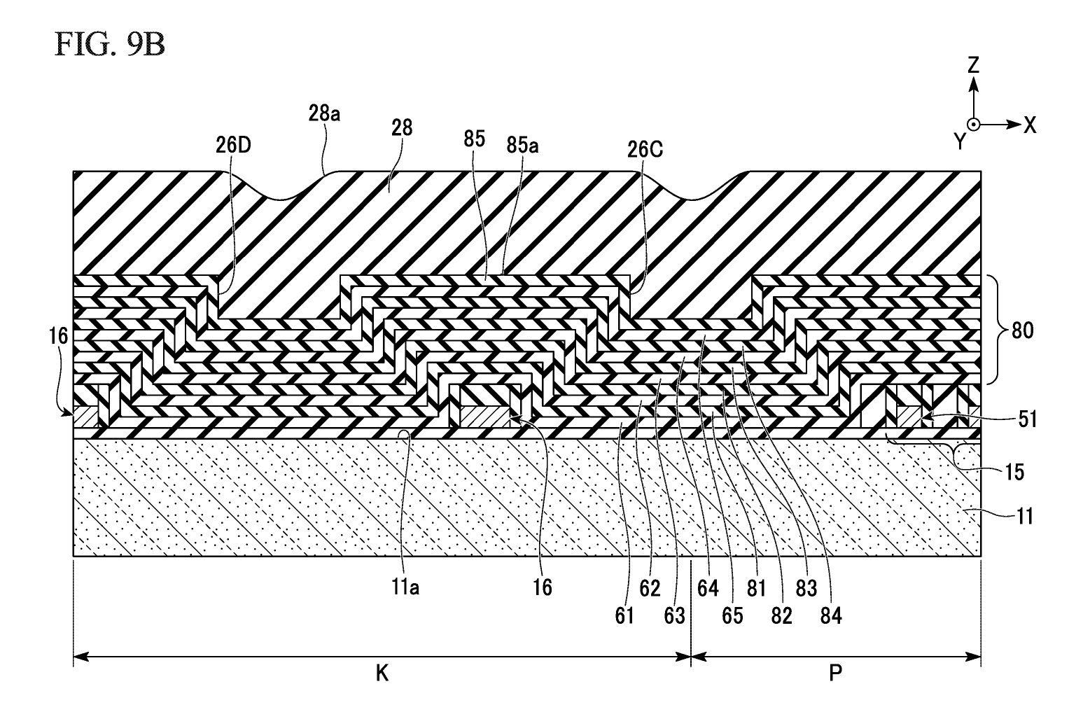

To obtain the structure shown in FIGS. 9A and 9B, the interlayer insulating film 28 is formed to cover the layered insulation body 80 in a thickness to fill the recessed portions 26A to 26D (a fifth process).

The upper surface 28a of the interlayer insulating film 28 at this stage is shaped to follow the contour of the upper surface side of the layered insulation body 80. As the interlayer insulating film 28, for example, a silicon oxide film may be used.

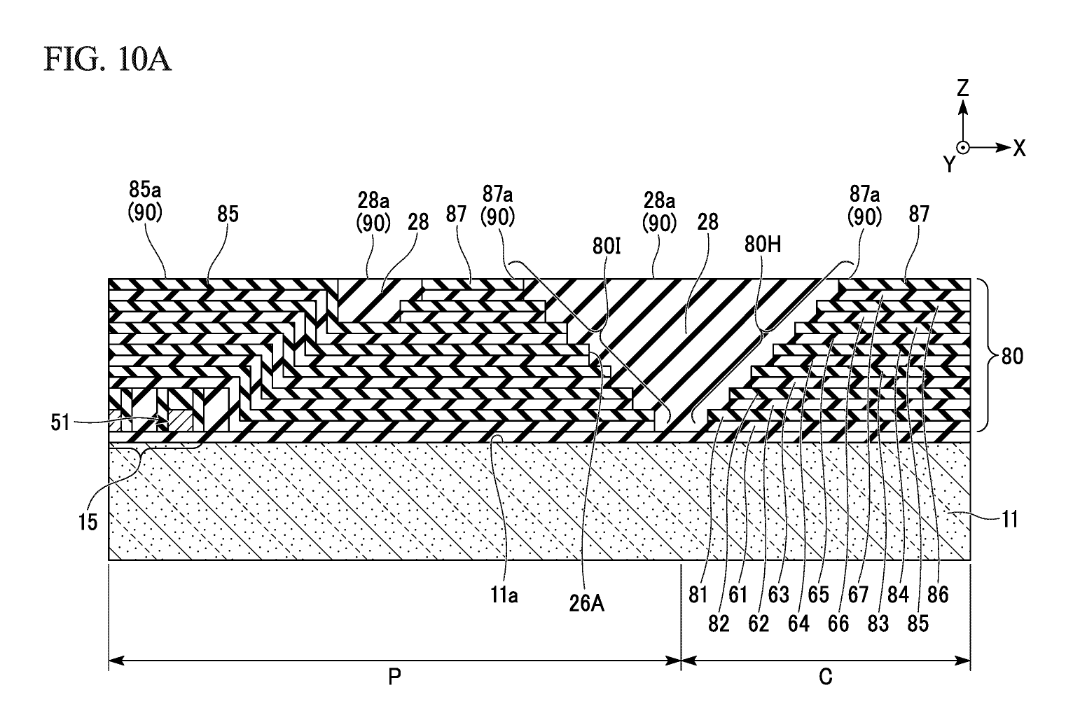

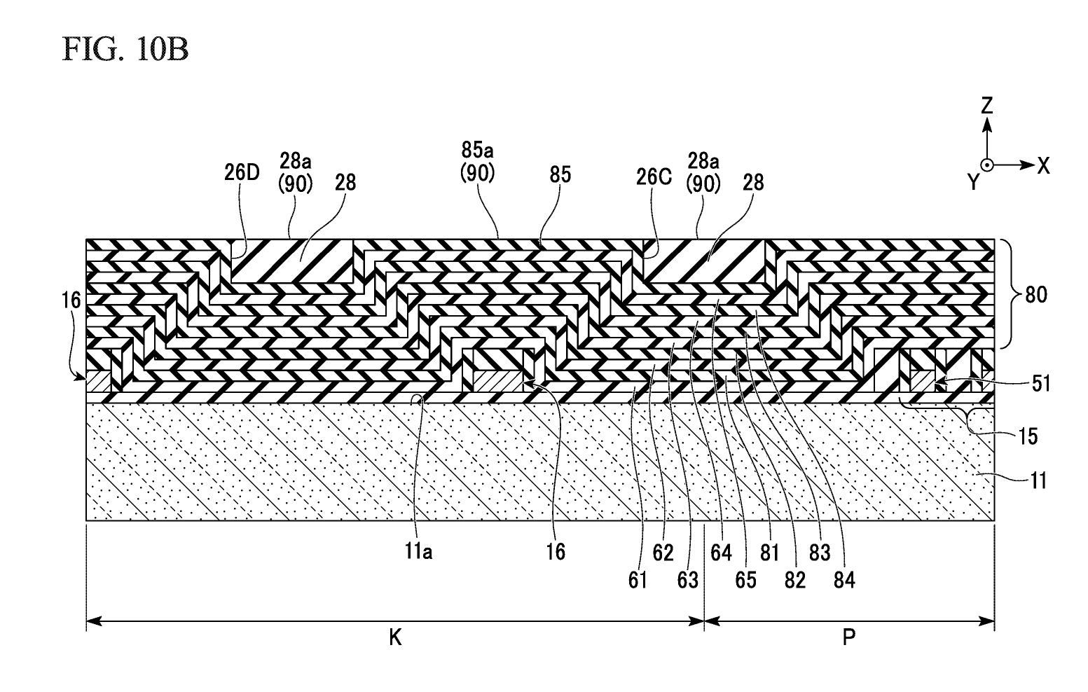

To obtain the structure shown in FIGS. 10A and 10B, the upper surface 85a of the sacrificial insulating layer 85 above the first transistor group 15 and the second transistors 16, the upper surface 87a of the uppermost layer of the first stepped part 80H, the upper surface 87a of the uppermost layer of the second stepped part 80I, and the upper surface 28a of the interlayer insulating film 28 are formed on the same plane 90 by a planarization process in which an upper portion of the interlayer insulating film 28 is polished (a sixth process).

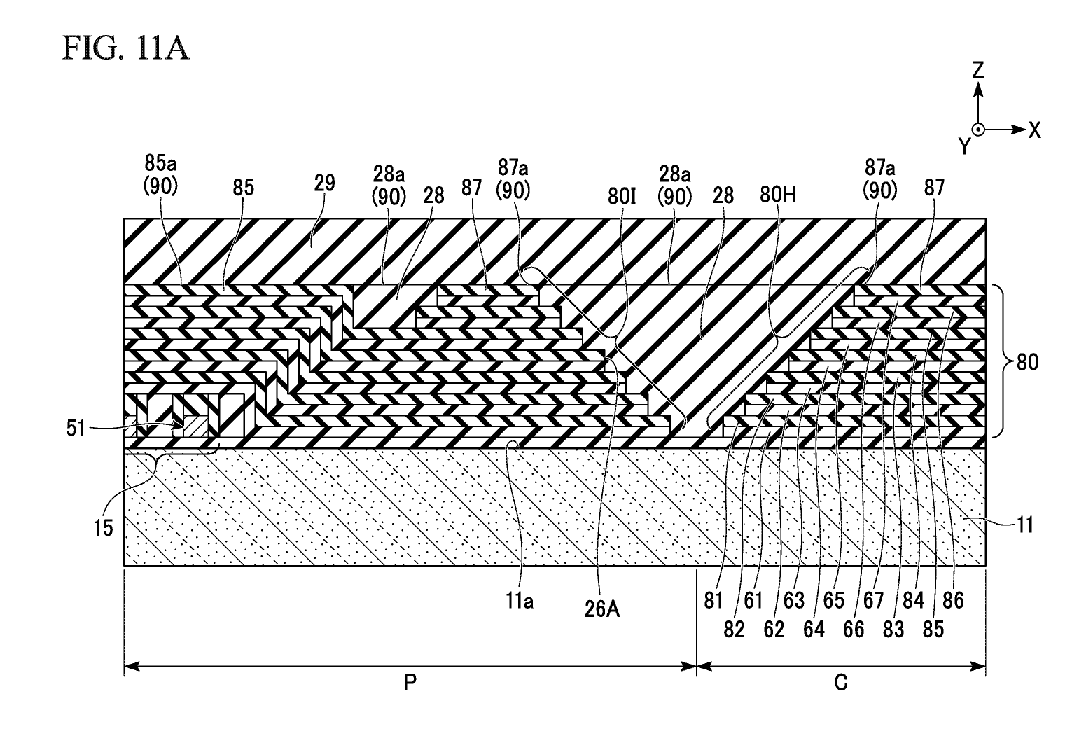

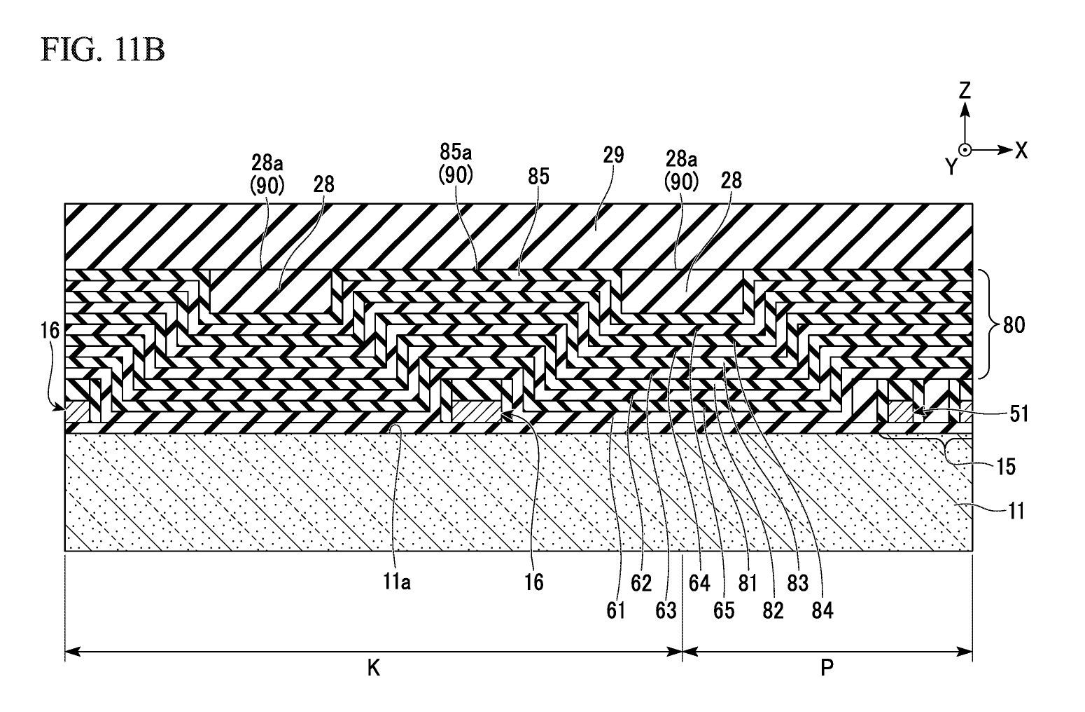

To obtain the structure shown in FIGS. 11A and 11B, the thickness adjustment interlayer insulating film 29 which covers the same plane 90 is formed. As the thickness adjustment interlayer insulating film 29, for example, a silicon oxide film may be used.

After the thickness adjustment interlayer insulating film 29 is formed, the beam columnar body 34 shown in FIG. 3 is formed.

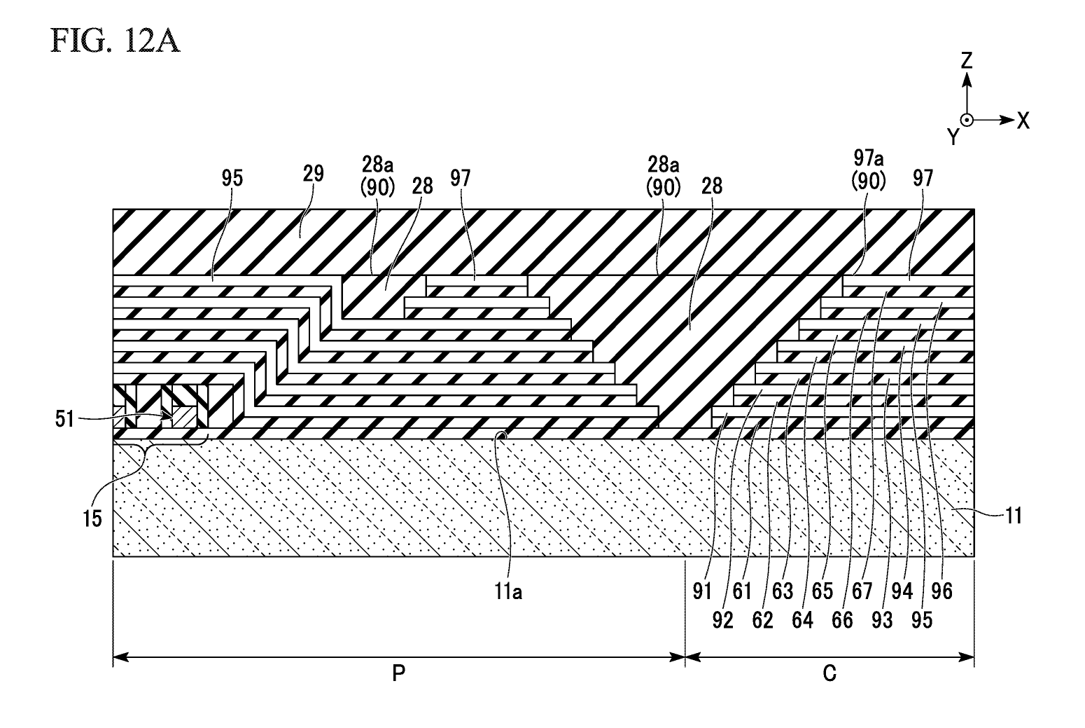

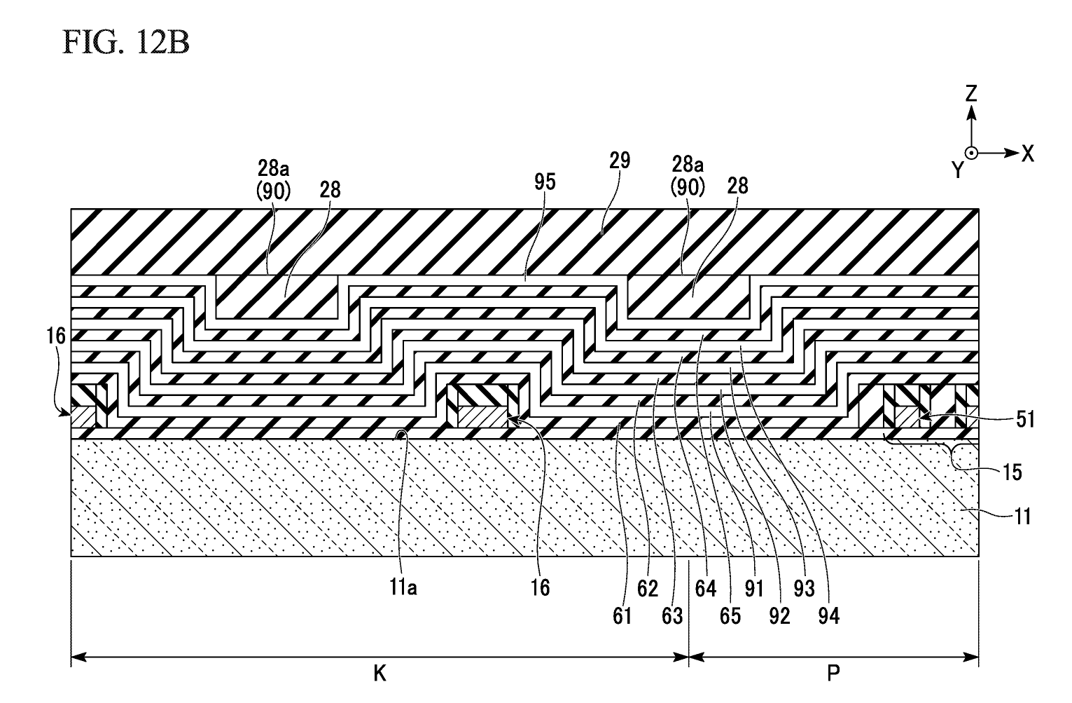

To obtain the structure shown in FIGS. 12A and 12B, the sacrificial insulating layers 81 to 87 are selectively removed by wet etching to form spaces 91 to 97. As the etchant, for example, thermal phosphoric acid may be used.

Thereafter, the conductive layers 71 to 77 which fill the spaces 91 to 97 are formed so that the insulating layers 61 to 67 and the conductive layers 71 to 77 are alternately layered as shown in FIGS. 4A and 4B, and thereby the layered structure 25 in which the first stepped part 25D and the second stepped part 25E are provided is formed (a seventh process).

A conductive material of the conductive layers 71 to 77 includes, for example, tungsten.

After the seventh process, the contact interconnections 35 to 39, the plurality of conductive lines 43, and the conductive line 45 as shown in FIG. 3 are formed, and the semiconductor memory device 1 is manufactured by cutting the scribe region K using a dicer.

According to the semiconductor memory device 1 according to the first embodiment, since the second stepped part 25E is formed to be continuous from the uppermost surface 77a of the layered structure 25 to the gate insulating film 13, the interlayer insulating film 28 which fills the recessed portion 26A can be formed by each single process of film-depositing and polishing, and thereby an amount of dishing on the upper surface 28a of the interlayer insulating film 28 can be reduced compared to the case in which the polishing process is performed multiple times.

Also, since the width of the recessed portion 26A in the X direction can be reduced by disposing the first stepped part 25D and the second stepped part 25E near each other, an amount of dishing of the interlayer insulating film 28 to fill the recessed portion 26A can be further reduced.

### Second Embodiment

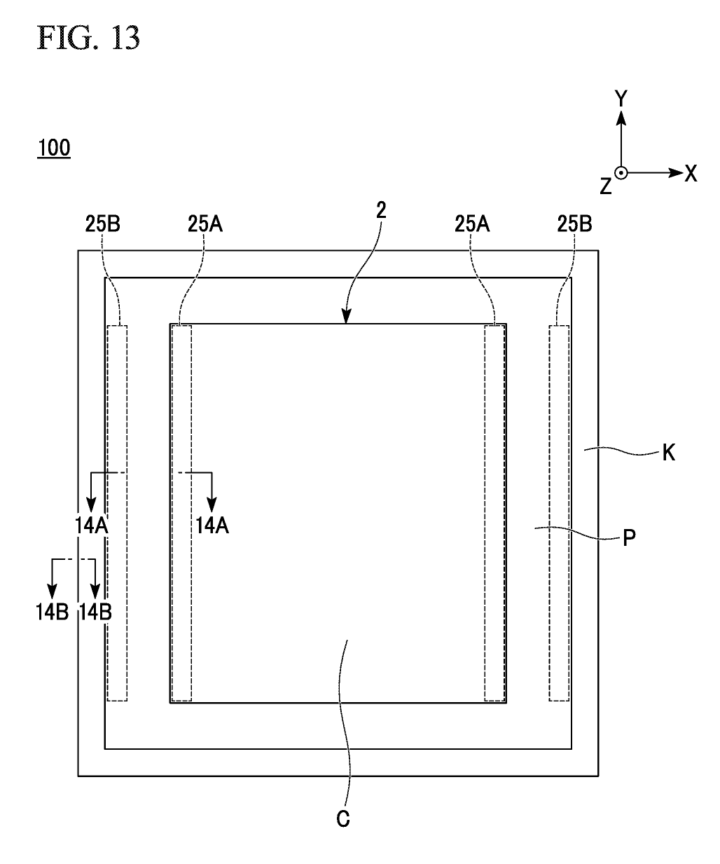

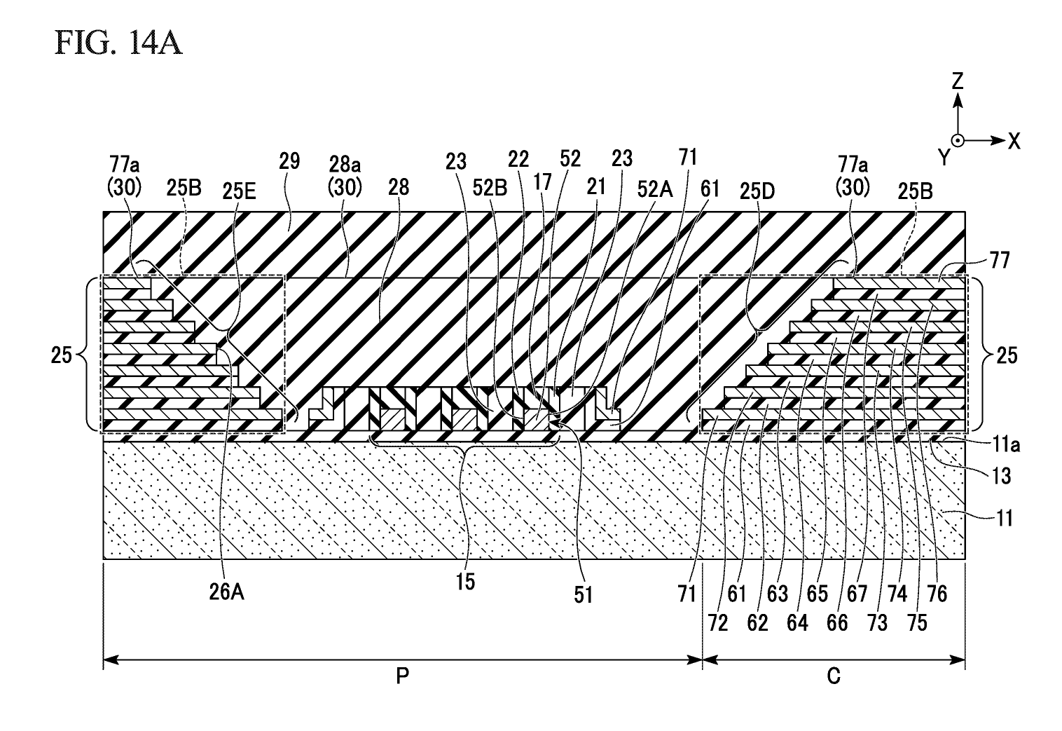

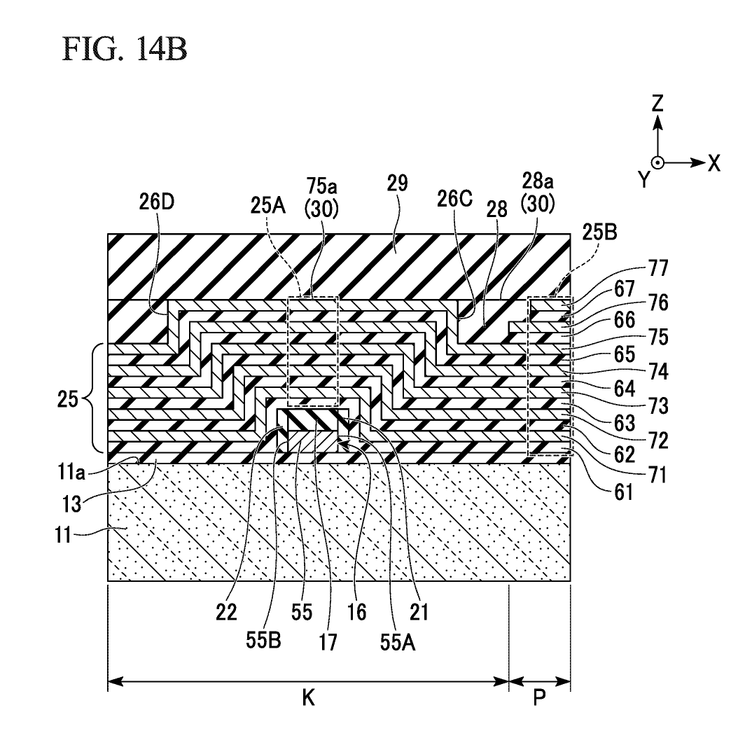

FIG. 13 is a plan view of a semiconductor memory device of a second embodiment. FIG. 14A is a cross-sectional view taken along the line 14A-14A of the semiconductor memory device shown in FIG. 13. FIG. 14B is a cross-sectional view taken along the line 14B-14B of the semiconductor memory device shown in FIG. 13.

According to FIGS. 13, 14A and 14B, a semiconductor memory device 100 according to the second embodiment is configured to be similar to the semiconductor memory device 1 according to the first embodiment except that a formation position of a second stepped part 25E is changed so that a first transistor group 15 is disposed in a recessed portion 26A.

The second stepped part 25E is disposed between the first transistor group 15 and a scribe region K in a peripheral circuit region P. The first transistor group 15 is exposed from a layered structure 25.

Only an interlayer insulating film 28 and a thickness adjustment interlayer insulating film 29 which are layered are disposed on a cap insulating film 17.

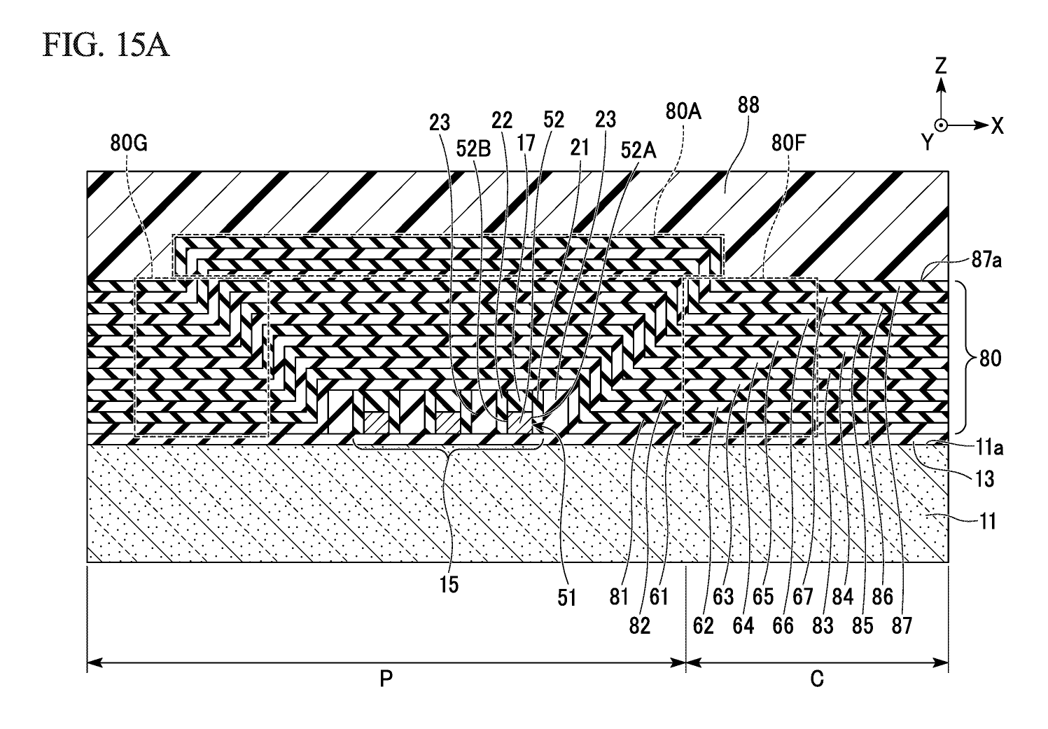

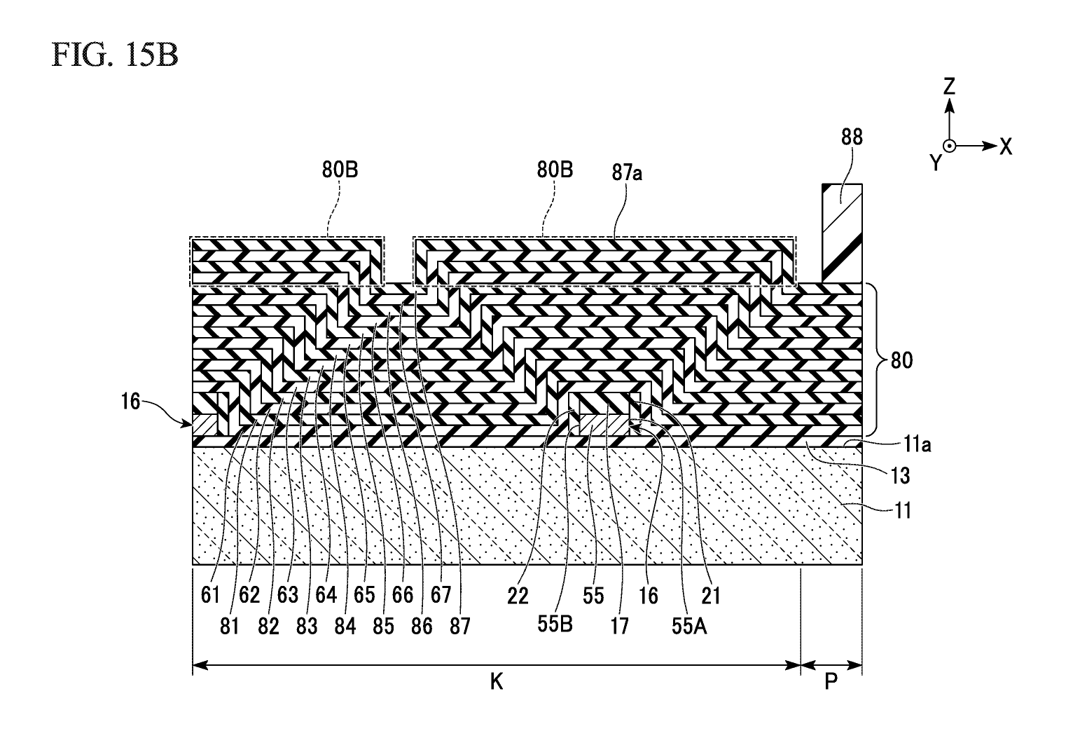

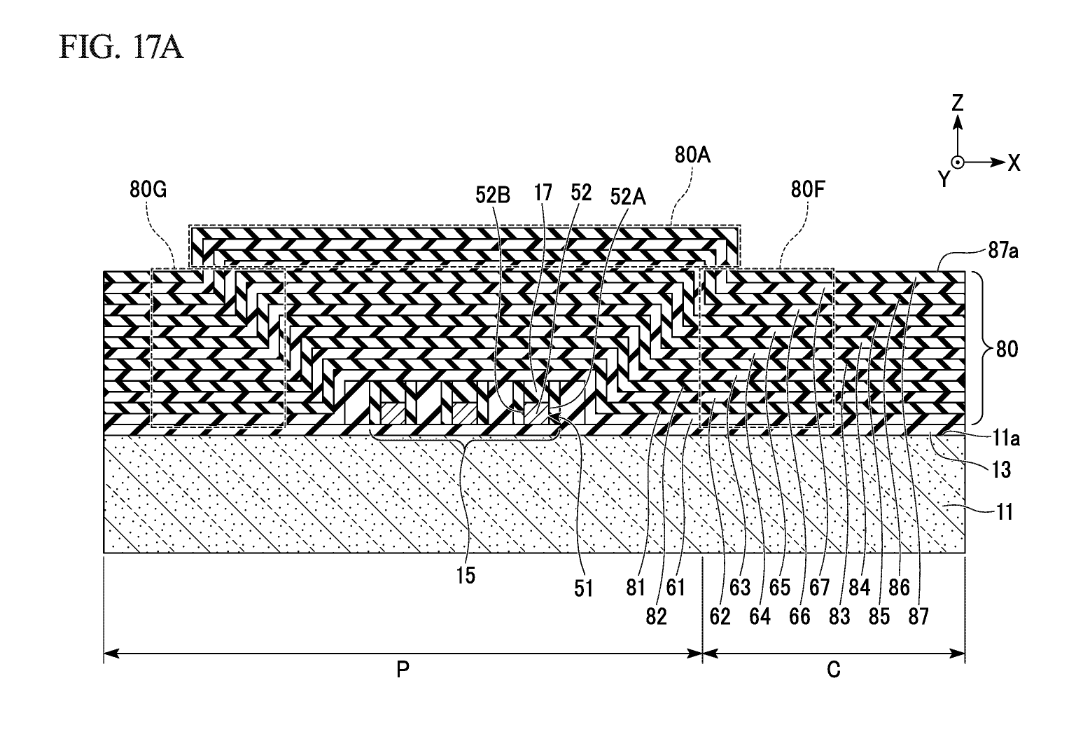

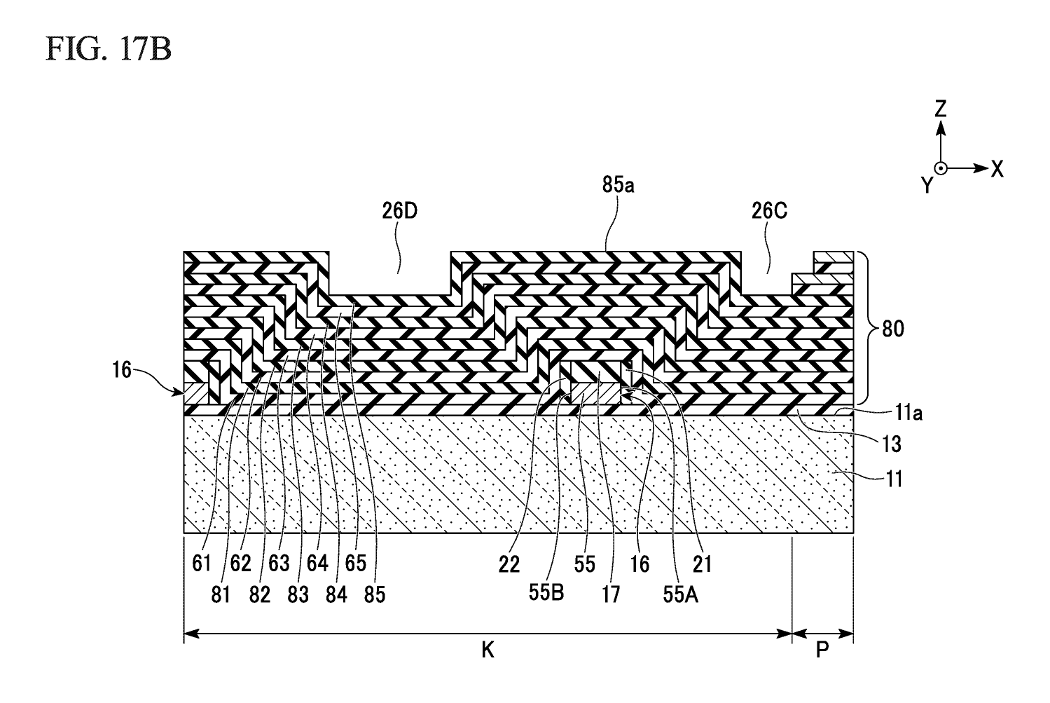

A method of manufacturing the semiconductor memory device 100 according to the second embodiment will be described with reference to FIGS. 15A to 21A and FIGS. 15B to 21B.

FIGS. 15A to 21A and FIGS. 15B to 21B are cross-sectional views showing a process of manufacturing a semiconductor memory device according to the second embodiment.

To obtain the structure shown in FIGS. 15A and 15B, a process similar to the process shown in FIGS. 5A and 5B is performed to form a gate insulating film 13, the first transistor group 15, a plurality of second transistors 16, the cap insulating film 17, lateral walls 21 and 22, an insulating film 23, and a layered insulation body 80 (a first process and a second process).

In this stage, a protrusion 80A disposed above the first transistor group 15 and a protrusion 80B disposed above the second transistors 16 are formed.

The protrusions 80A and 80B protrude upward from an upper surface 87a of the uppermost layer of the layered insulation body 80 formed in a memory cell region C.

After the layered insulation body 80 is formed, an etching mask 88 which covers the protrusion 80A on the upper surface 87a (the uppermost surface) of the layered insulation body 80 formed in the memory cell region C and the peripheral circuit region P and exposes the protrusion 80B is formed.

The etching mask 88 covers an upper surface of a first step formation region 80F and a second step formation region 80G which are formed of the layered insulation body 80.

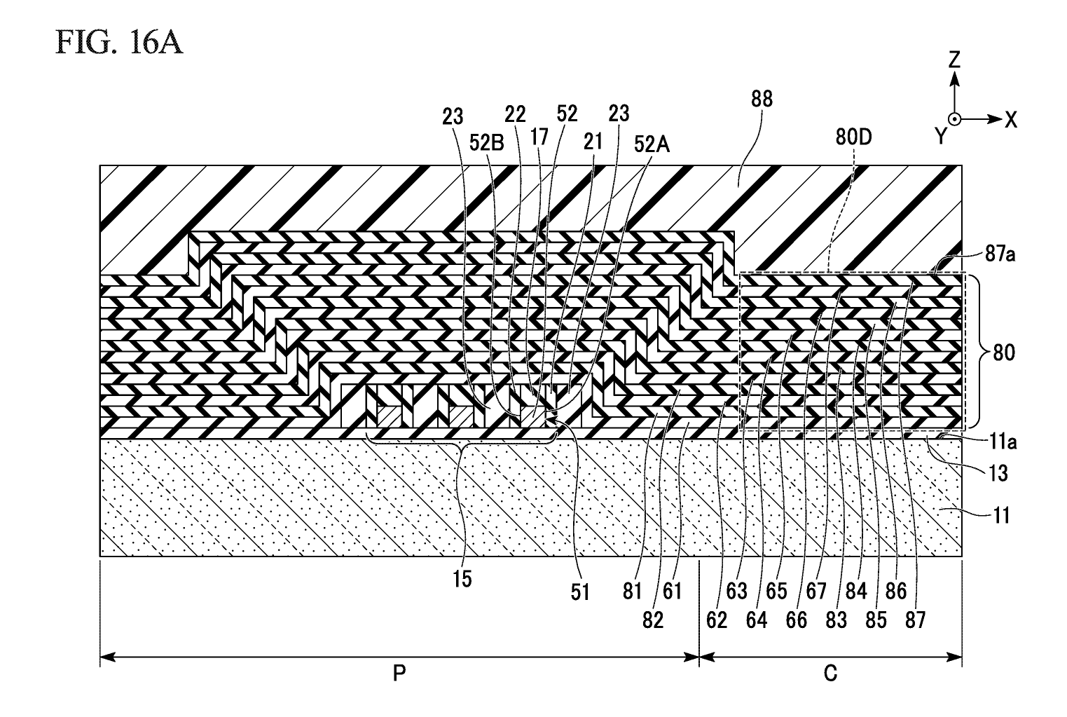

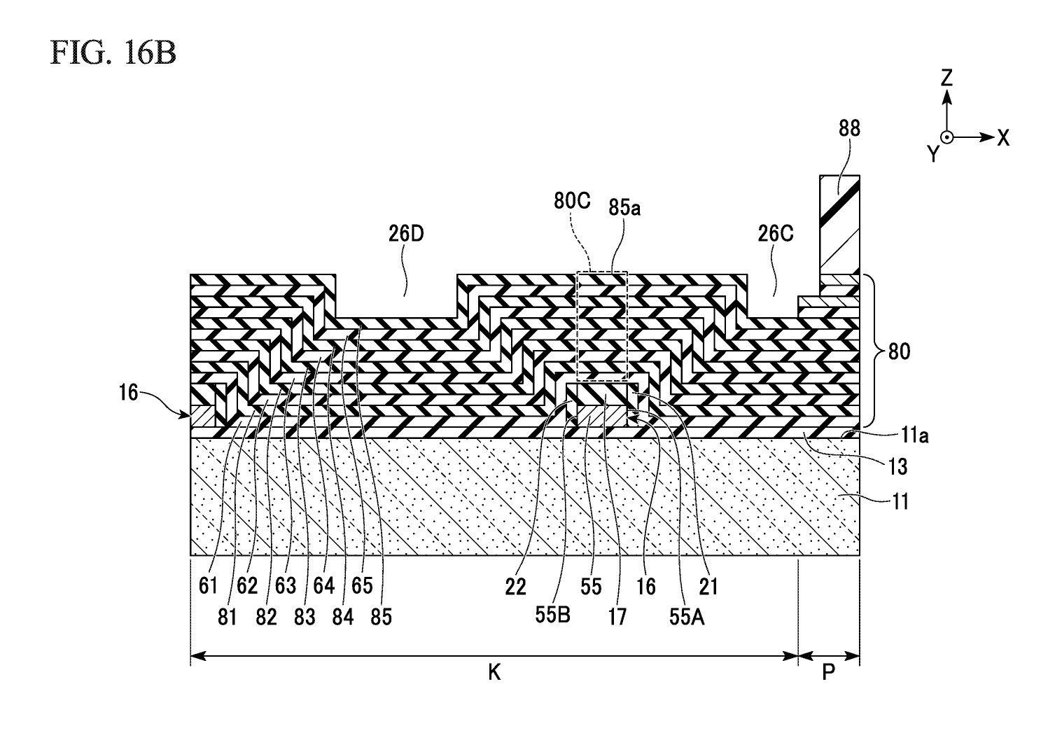

To obtain the structure shown in FIGS. 16A and 16B, the protrusion 80B which is an upper portion of the layered insulation body 80 is removed by anisotropic etching to form recessed portions 26C and 26D, and a first layered portion 80C disposed above the second transistors 16 and formed of the layered insulation body 80.

In this case, a height from the main surface 11a of the semiconductor substrate 11 to an upper surface 85a of the first layered portion 80C, and a height from the main surface 11a of the semiconductor substrate 11 to the upper surface 87a of a second layered portion 80D disposed in the memory cell region C and formed of the layered insulation body 80 are made to be the same (a third process).

For the anisotropic etching of the above-described third process, the same technique as the etching method described in the third process according to the first embodiment may be used.

After the third process, the etching mask 88 is removed.

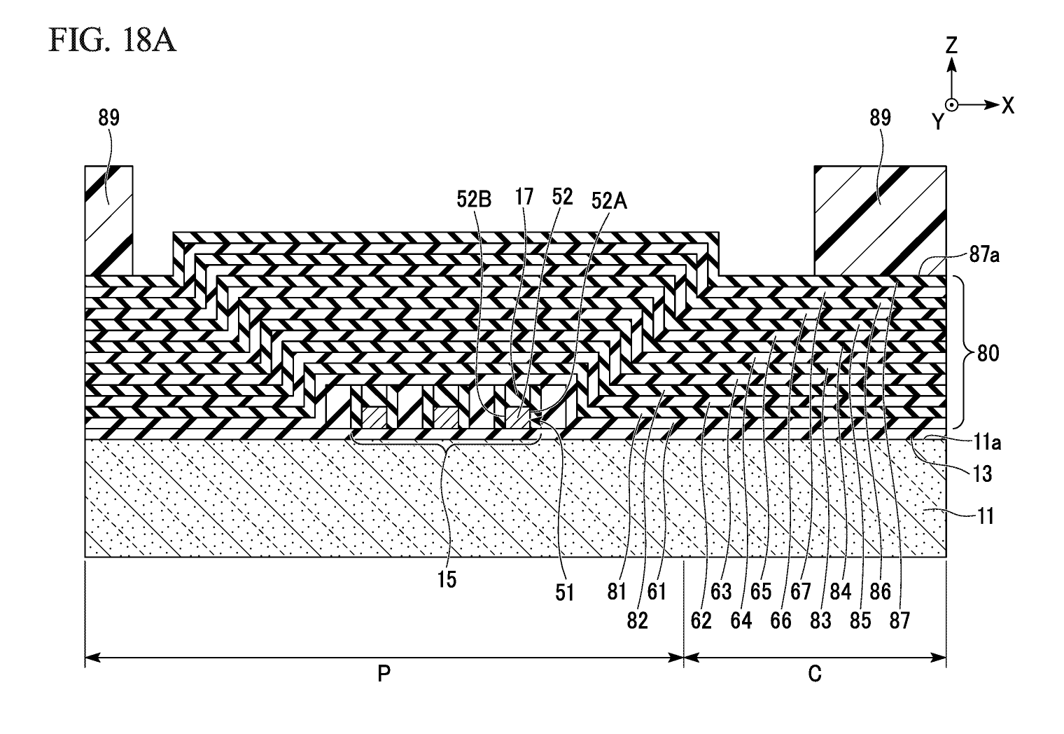

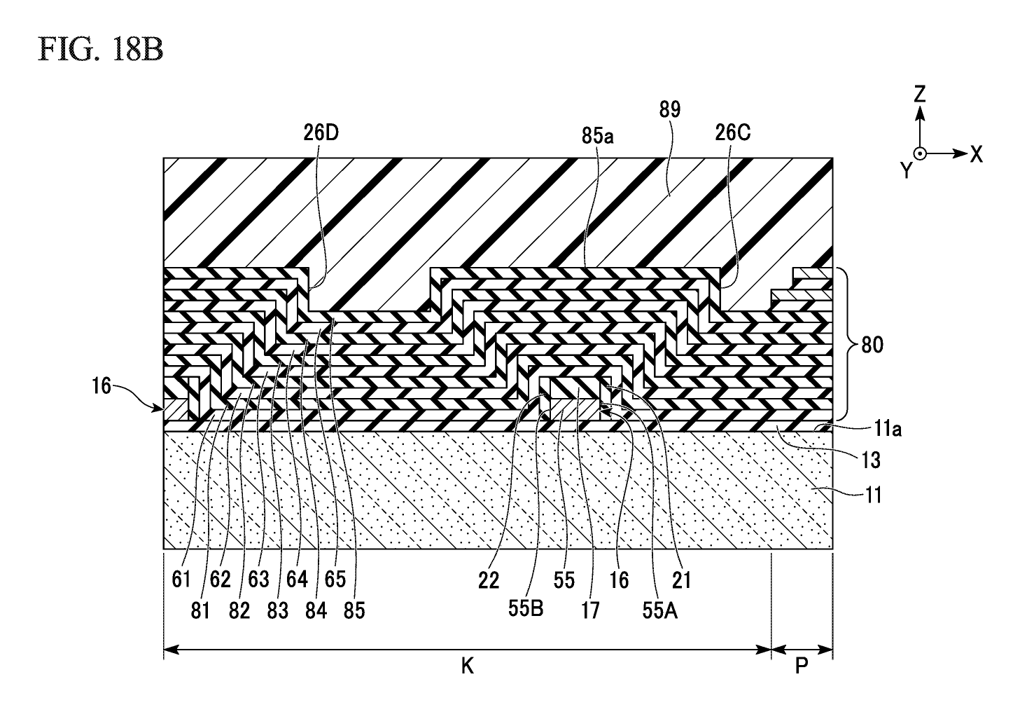

To obtain the structure shown in FIGS. 18A and 18B, an etching mask 89 that exposes the formation region of the recessed portion 26A is formed on the layered insulation body 80.

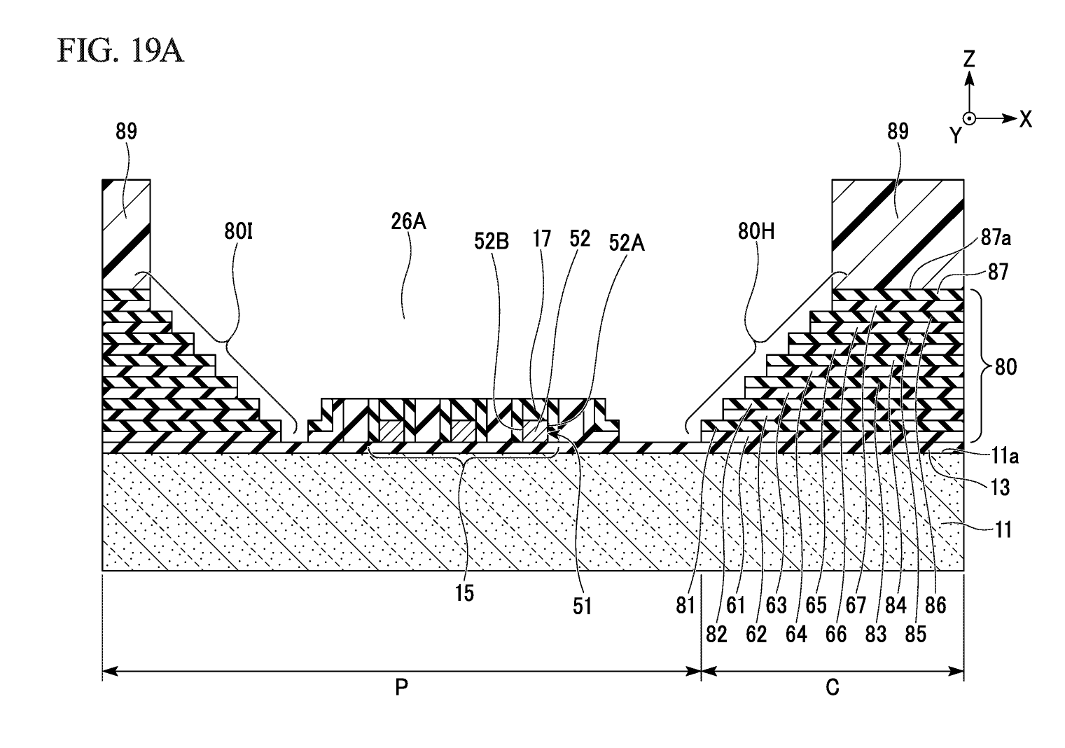

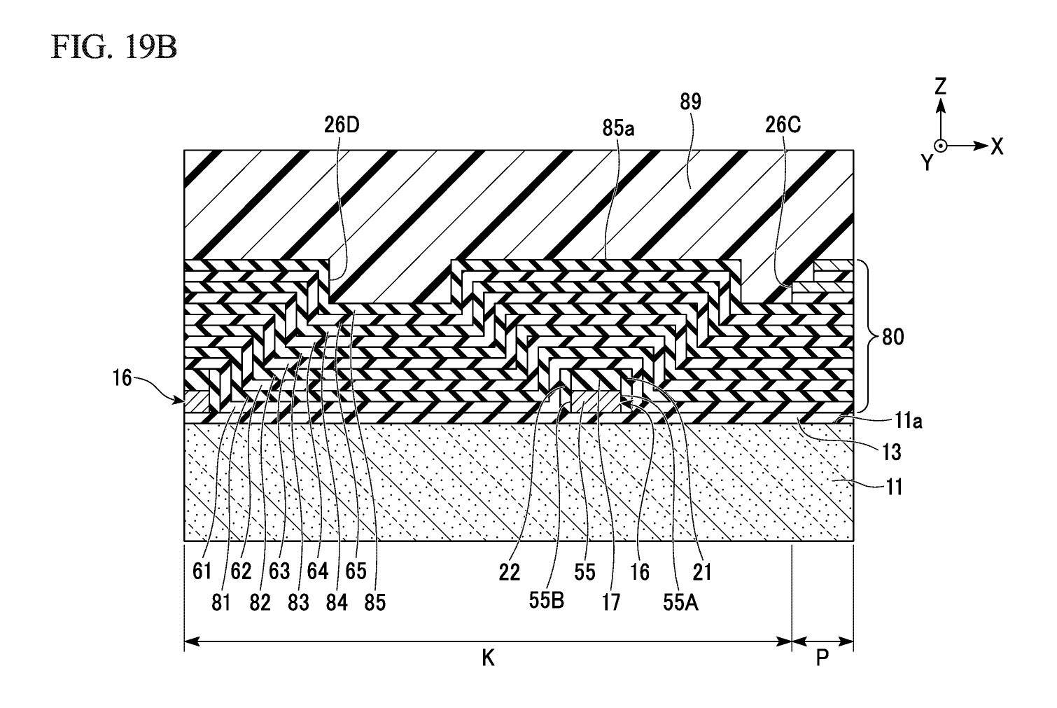

To obtain the structure shown in FIGS. 19A and 19B, the first step formation region 80F, the second step formation region 80G, and the layered insulation body 80 (including the protrusion 80A) positioned between the first step formation region 80F and the second step formation region 80G are etched in order to collectively form a first stepped part 80H, a second stepped part 80I, and the recessed portion 26A (a fourth process).

The etching mask 89 is removed after the first stepped part 80H, the second stepped part 80I, and the recessed portion 26A are formed.

In the fourth process, the first stepped part 80H and the second stepped part 80I are formed in a state in which the first transistor group 15 is exposed from the layered insulation body 80.

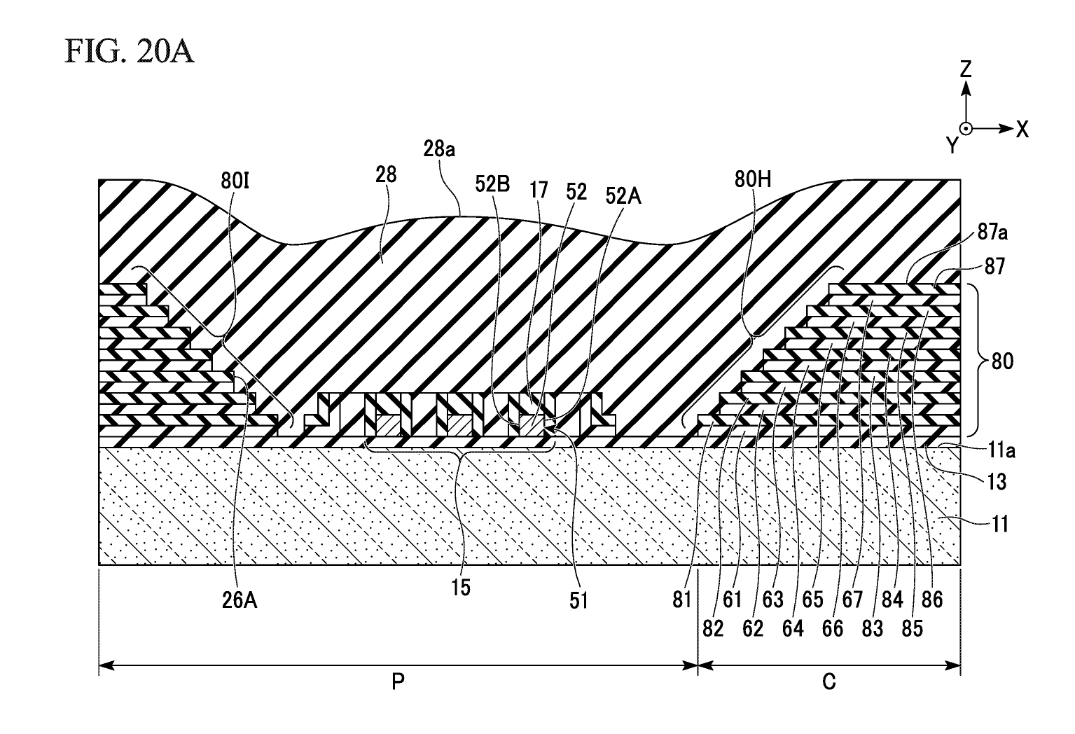

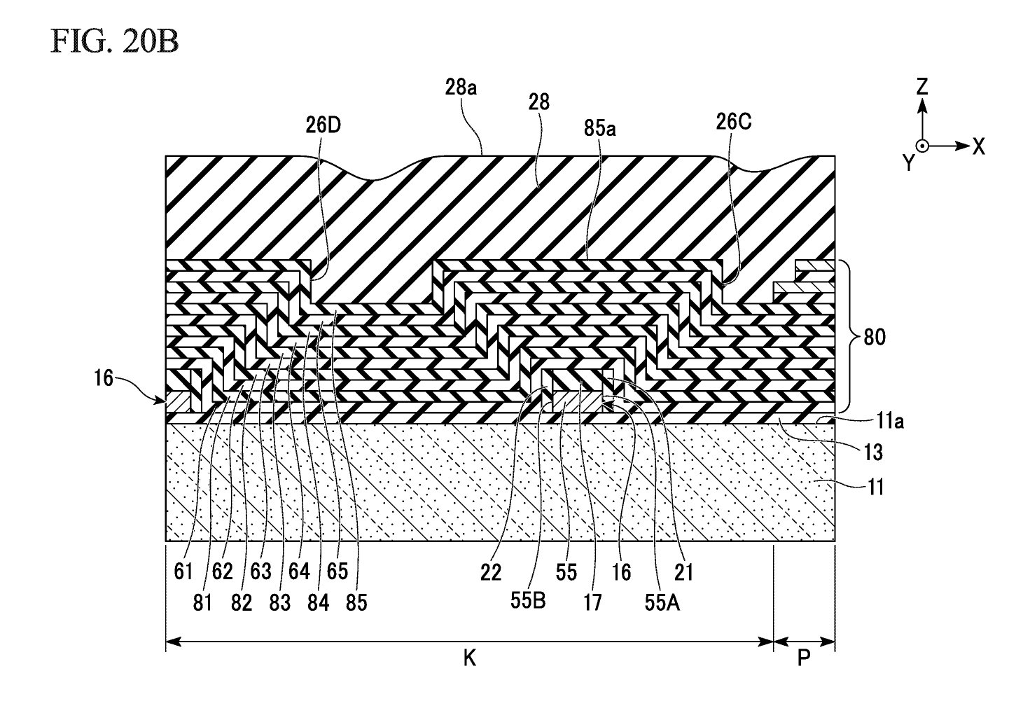

To obtain the structure shown in FIGS. 20A and 20B, the interlayer insulating film 28 is formed to cover the layered insulation body 80 at a thickness at which the recessed portions 26A, 26C and 26D are filled(a fifth process).

An upper surface 28a of the interlayer insulating film 28 at this stage has a concave-convex shape which follows the contour of the upper surface side of the layered insulation body 80.

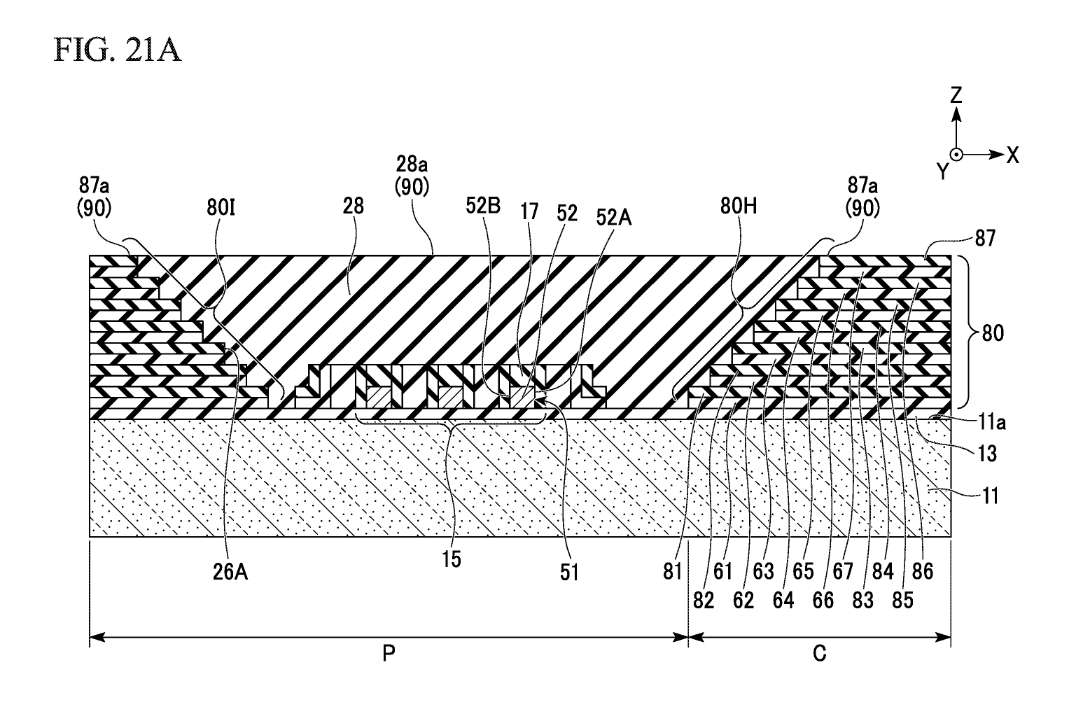

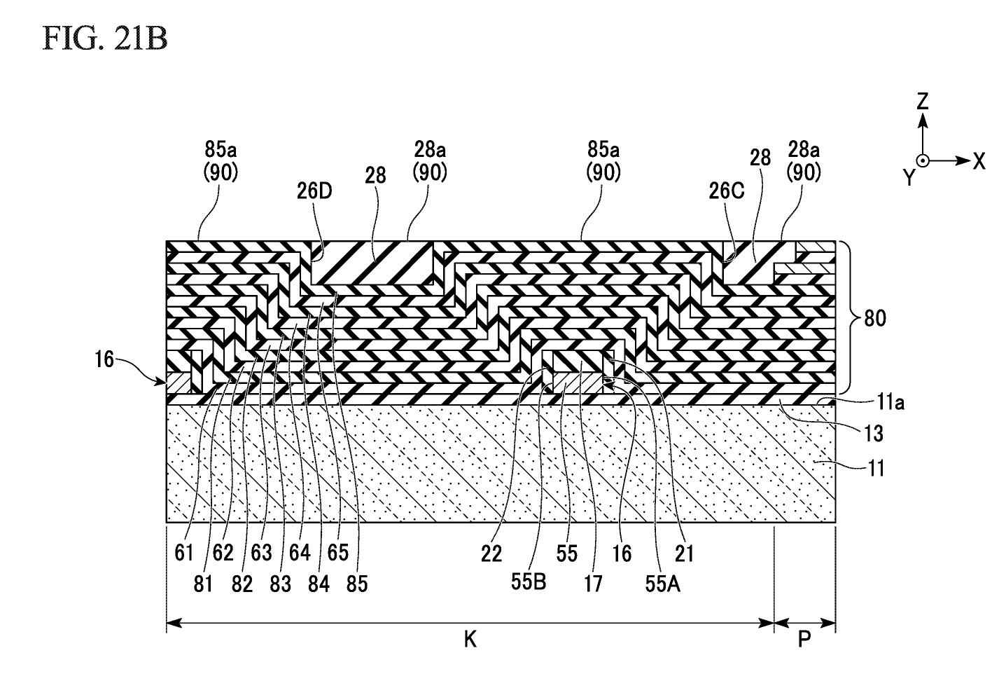

To obtain the structure shown in FIGS. 21A and 21B, the upper surface 85a of a sacrificial insulating layer 85 above the first transistor group 15 and the second transistors 16, the upper surface 87a of the uppermost layer of the first stepped part 80H, the upper surface 87a of the uppermost layer of the second stepped part 80I, and the upper surface 28a of the interlayer insulating film 28 are formed on the same plane 90 by a planarization process in which an upper portion of the interlayer insulating film 28 is polished (a sixth process).

After the sixth process, a thickness adjustment interlayer insulating film 29 which covers the same plane 90 and the beam columnar body 34 shown in FIG. 3 are formed in sequence.

Thereafter, a process similar to the process shown in FIGS. 12A and 12B is performed to form the layered structure 25 in which the first stepped part 25D and the second stepped part 25E are provided (a seventh process).

After the seventh process, contact interconnections 35 to 39, a plurality of conductive lines 43, and a conductive line 45 as shown in FIG. 3 are formed, and the semiconductor device 1 is manufactured by cutting the scribe region K using a dicer.

According to the semiconductor memory device 100 according to the second embodiment, only the interlayer insulating film 28 and the thickness adjustment interlayer insulating film 29 on which the anisotropic etching is easy to perform are disposed on the first transistor group 15 while the layered structure 25 in which conductive layers 71 to 77 are layered is not provided thereon.

Therefore, a contact hole in which a contact interconnection is disposed can be easily formed using the anisotropic etching when forming the contact interconnection that reaches an impurity diffusion region (not shown in figure) which constitutes a first transistor 51.

Also, although the case of one step is taken as an example of the first stepped parts 25D and 80H and the second stepped parts 25E and 80I in the first and second embodiments, the first stepped parts 25D and 80H and the second stepped parts 25E and 80I may be, for example, a grid-shaped step.

According to at least one embodiment described above, since the second stepped part 25E is formed to be continuous from the uppermost surface 77a of the layered structure 25 to the gate insulating film 13 and the interlayer insulating film 28 which fills the recessed portion 26A can be formed by each single process of film-depositing and polishing, an amount of dishing on the upper surface 28a of the interlayer insulating film 28 can be reduced compared to the case in which the polishing process is performed multiple times.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor substrate having a main surface;
a gate insulating film which covers the main surface of the semiconductor substrate;
a memory cell array disposed in a memory cell region;
a first transistor disposed in a peripheral circuit region which surrounds the memory cell region, the first transistor having a first gate electrode on the gate insulating film;
a second transistor disposed in a scribe region which surrounds the peripheral circuit region, the second transistor having a second gate electrode on the gate insulating film;
a first stepped structure disposed in the memory cell region and a second stepped structure disposed in the peripheral circuit region, the first and second stepped structures facing each other and each including a plurality of insulating layers and conductive layers that are alternately stacked on the main surface of the semiconductor substrate; and
an interlayer insulating film disposed in a region where the first stepped structure and the second stepped structure face each other, wherein
an upper surface of an uppermost layer of the first stepped structure, an upper surface of an uppermost layer of the second stepped structure, and an upper surface of the interlayer insulating film are formed on the same plane.

2. The semiconductor memory device according to claim 1, wherein
the first stepped structure has a lowermost layer that extends in a first direction towards the second stepped structure more than the uppermost layer of the first stepped structure, and
the second stepped structure has a lowermost layer that extends in a second direction towards the first stepped structure more than the uppermost layer of the second stepped structure,
the first and second directions being opposite directions.

3. The semiconductor memory device according to claim 2, wherein
the first stepped structure has middle layers that extend in the first direction towards the second stepped structure more than the uppermost layer of the first stepped structure but less than the lowermost layer of the first stepped structure, and
the second stepped structure has middle layers that extend in the second direction towards the first stepped structure more than the uppermost layer of the second stepped structure but less than the lowermost layer of the second stepped structure.

4. The semiconductor memory device according to claim 1, wherein the scribe region extends in a third direction that is parallel to the main surface of the semiconductor substrate and perpendicular to the first and second directions.

5. The semiconductor memory device according to claim 4, wherein the second gate electrode extends in the third direction.

6. The semiconductor memory device according to claim 1, further comprising:
a first stacked structure in the scribe region including a plurality of insulating layers and conductive layers that are alternately stacked above the second gate electrode; and
a second stacked structure in the peripheral circuit region including a plurality of insulating layers and conductive layers that are alternately stacked above the first gate electrode.

7. The semiconductor memory device according to claim 6, wherein
the number of stacked layers in each of the first stacked structure and the second stacked structure is fewer than the number of stacked layers in either the first stepped structure or the second stepped structure.

8. The semiconductor memory device according to claim 6, wherein the conductive layers of the first stacked structure are electrically connected to the conductive layers in the second stacked structure, respectively.

9. The semiconductor memory device according to claim 6, wherein the conductive layers of the second stacked structure are each electrically connected to one of the conductive layers in the second stepped structure.

10. The semiconductor memory device according to claim 9, wherein the uppermost conductive layer of the second stepped structure is not electrically connected to any of the conductive layers in the second stacked structure.

11. The semiconductor memory device according to claim 9, wherein the two uppermost conductive layers of the second stepped structure are not electrically connected to any of the conductive layers in the second stacked structure.

12. A method of manufacturing a semiconductor memory device comprising:
forming a gate insulating film on a main surface of a semiconductor substrate;
forming a first transistor in a peripheral circuit region which surrounds a memory cell region and a second transistor in a scribe region which surrounds the peripheral circuit region, on an upper surface of the gate insulating film, the first transistor having a first gate electrode on the gate insulating film, and the second transistor having a second gate electrode on the gate insulating film;
alternately stacking a plurality of insulating layers and sacrificial insulating layers to form a multi-layered insulation body on the upper surface of the gate insulating film, the first transistor, and the second transistor;
removing at least an upper portion of the multi-layered insulation body formed in the scribe region to form a first multi-layered portion disposed above the second transistor, causing a height from the upper surface of the gate insulating film to an upper surface of the first multi-layered portion to be equal to a height from the upper surface of the gate insulating film to an upper surface of a second multi-layered portion of the multi-layered insulation body disposed in the memory cell region;
etching a first region positioned at an end portion of the memory cell region, a second region positioned in the peripheral circuit region and configured to face the first region in a direction perpendicular to an extending direction of the scribe region, and an area positioned between the first region and the second region to form a first stepped structure at the end portion of the memory cell region which extends from the upper surface of the multi-layered insulation body to the upper surface of the gate insulating film, a second stepped structure in the peripheral circuit region, which extends from an upper surface of the multi-layered insulation body to the upper surface of the gate insulating film and faces the first stepped structure, and a recessed portion disposed between the first stepped structure and the second stepped structure;
forming an interlayer insulating film which covers the multi-layered insulation body so that the recessed portion is filled;
polishing the interlayer insulating film so that an upper surface of the uppermost layer of the first stepped structure, an upper surface of the uppermost layer of the second stepped structure, and an upper surface of the interlayer insulating film are on the same plane;
selectively removing the plurality of sacrificial insulating layers to form a plurality of spaces after the polishing; and
forming conductive layers which fill the plurality of spaces to form a multi-layered structure in which the plurality of insulating layers and conductive layers are alternately stacked.

13. The method of claim 12, wherein when etching the first region, the second region, and the area positioned between the first region and the second region,
the first stepped structure is formed so as to have a lowermost layer that extends in a first direction towards the second stepped structure more than the uppermost layer of the first stepped structure,
the second stepped structure is formed so as to have a lowermost layer that extends in a second direction towards the first stepped structure more than the uppermost layer of the second stepped structure, and
the first direction and the second direction are opposite directions.

14. The method of claim 13, wherein when etching the first region, the second region, and the area positioned between the first region and the second region,
the first stepped structure is formed so as to have middle layers that extend in the first direction towards the second stepped structure more than the uppermost layer of the first stepped structure but less than the lowermost layer of the first stepped structure, and
the second stepped structure is formed so as to have middle layers that extend in the second direction towards the first stepped structure more than the uppermost layer of the second stepped structure but less than the lowermost layer of the second stepped structure.

15. The method of claim 12, wherein the scribe region extends in a third direction that is parallel to the main surface of the semiconductor substrate and perpendicular to the first and second directions.

16. The method of claim 15, wherein the second gate electrode extends in the third direction.

17. The method of claim 12, wherein when removing at least an upper portion of the multi-layered insulation body formed in the scribe region,
a first stacked structure is formed in the scribe region so as to include a plurality of insulating layers and conductive layers that are alternately stacked above the second gate electrode, and
a second stacked structure is formed in the peripheral circuit region so as to include a plurality of insulating layers and conductive layers that are alternately stacked above the first gate electrode.

18. The method of claim 17, wherein
the number of stacked layers in each of the first stacked structure and the second stacked structure is fewer than the number of stacked layers in either the first stepped structure or the second stepped structure.

19. The method of claim 17, wherein the conductive layers of the first stacked structure are electrically connected to the conductive layers in the second stacked structure, respectively.

20. The method of claim 17, wherein the conductive layers of the second stacked structure are each electrically connected to one of the conductive layers in the second stepped structure.
